(19) United States
(12) Patent Application Publication
(10) Pub. No.: US 2026/0304877 A1
(43) Pub. Date: Oct. 1, 2026

(54) SEMICONDUCTOR MEMORY DEVICE INCLUDING PLURALITY OF SINGLE CRYSTALLINE SILICON LAYERS

(71) Applicant: Samsung Electronics Co., Ltd., Suwon-si (KR)

(72) Inventors: Yuyeon Kim, Suwon-si (KR); Moohyun Kim, Suwon-si (KR); Hyungjoon Kim, Suwon-si (KR); Siyeong Yang, Suwon-si (KR); Jaeho Jung, Suwon-si (KR)

(73) Assignee: Samsung Electronics Co., Ltd., Suwon-si (KR)

(21) Appl. No.: 19/457,682

(22) Filed: Jan. 23, 2026

(30) Foreign Application Priority Data
Mar. 26, 2025 (KR) 10-2025-0039044

(51) Int. Cl. H10D 62/834; H10B 12/00; H10D 1/68; H10D 62/40

(52) U.S. Cl. CPC H10D 62/834; H10B 12/03; H10B 12/482; H10B 12/488; H10B 12/50; H10D 1/714; H10D 62/405; H10B 12/05

(57) ABSTRACT

A semiconductor memory device includes a substrate and a plurality of single crystalline silicon layers arranged in a line in a vertical direction on the substrate and spaced apart from one another in the vertical direction, wherein, in each of the plurality of single crystalline silicon layers, a surface facing a lateral direction substantially orthogonal to the vertical direction is oriented along a (100) crystal plane, and, from among the plurality of single crystalline silicon layers, a lowest-level single crystalline silicon layer closest to the substrate includes metal impurities.

### CROSS-REFERENCE TO RELATED APPLICATIONS

This present application claims priority to and the benefit under 35 U.S.C. § 119(a)-(d) of Korean Patent Application No. 10-2025-0039044, filed on Mar. 26, 2025, in the Korean Intellectual Property Office, the entire disclosure of which is incorporated herein by reference.

### FIELD

The disclosed concepts relate to a semiconductor memory device, and more particularly, to a semiconductor device including a plurality of single crystalline silicon layers arranged in a line in a substantially vertical direction.

### BACKGROUND

Due to the development of electronics technology, the downscaling of semiconductor devices has rapidly progressed in recent years. Thus, the miniaturization of memory cells is required, and typical memory cells have limitations in maintaining high integration density and reliability. Accordingly, it is necessary to develop a semiconductor memory device having a structure that facilitates miniaturization and high integration of memory cells.

### SUMMARY

The disclosed concepts provide a semiconductor memory device having a three-dimensional (3D) structure, which has improved electrical properties and reliability.

According to aspects of the disclosed concepts, there is provided a semiconductor memory device including a substrate and a plurality of single crystalline silicon layers arranged in a line in a vertical direction on the substrate and spaced apart from one another in the vertical direction, wherein, in each of the plurality of single crystalline silicon layers, a surface facing a lateral direction substantially orthogonal to the vertical direction is oriented along a (100) crystal plane, and, from among the plurality of single crystalline silicon layers, a lowest-level single crystalline silicon layer closest to the substrate includes metal impurities.

According to aspects of the disclosed concepts, there is provided a semiconductor memory device including a substrate and a memory cell block including a plurality of memory cells arranged on the substrate, the memory cell block having a three-dimensional structure, wherein the plurality of memory cells are repeatedly arranged in a first lateral direction, a second lateral direction, and a vertical direction and include a plurality of active regions, each of which includes a single crystalline silicon layer, wherein the first lateral direction and the second lateral direction are substantially orthogonal to one another, and the vertical direction is substantially perpendicular to each of the first lateral direction and the second lateral direction, in each of the plurality of active regions, a first surface facing the second lateral direction is oriented along a (100) crystal plane, and, from among the plurality of active regions, lowest-level active regions closest to the substrate in the vertical direction include metal impurities.

According to aspects of the disclosed concepts, there is provided a semiconductor memory device including a substrate and a memory cell block having a three-dimensional structure, the memory cell block including a plurality of memory cells that are repeatedly arranged on a main surface of the substrate in a first lateral direction, a second lateral direction, and a vertical direction, wherein the first lateral direction and the second lateral direction are substantially parallel to the main surface and substantially orthogonal to one another, and the vertical direction is substantially perpendicular to the main surface of the substrate, wherein the memory cell block includes a plurality of active regions arranged in a line in the vertical direction on the substrate, each active region including a single crystalline silicon layer, a plurality of word lines, each word line surrounding a selected one of the plurality of active regions and extending in the second lateral direction, the plurality of word lines overlapping one another in the vertical direction, a bit line extending in the vertical direction on the substrate, the bit line being connected to one side of each of the plurality of active regions, and a plurality of capacitors, each capacitor including a first electrode configured to be connected to another side of a selected one of the plurality of active regions, wherein, in each of the plurality of active regions, a first surface facing the second lateral direction is oriented along a (100) crystal plane, from among the plurality of active regions, a lowest-level active region closest to the substrate in the vertical direction includes metal impurities, and, from among the plurality of active regions, active regions that are spaced apart in the vertical direction from the substrate with the lowest-level active region therebetween do not include metal impurities.

According to aspects of the disclosed concepts, there is provided a method of manufacturing a semiconductor memory device. The method includes forming an amorphous insulating film on a substrate. A stack structure in which a plurality of amorphous silicon layers and a plurality of sacrificial layers are alternately stacked one-by-one in a vertical direction is formed on the amorphous insulating film. An alignment insulating layer is formed on the stack structure. A sacrificial amorphous silicon layer is formed on the alignment insulating layer. A metal-containing layer is formed to cover a top surface of the sacrificial amorphous silicon layer. The resultant structure in which the metal-containing layer is formed is thermally treated to transform a portion of the sacrificial amorphous silicon layer into a metal silicide layer. The metal-containing layer may be removed to expose a top surface of the metal silicide layer. The resultant structure in which the metal silicide layer is exposed is thermally treated to diffuse metal elements from the metal silicide layer through the alignment insulating layer. Thus, a plurality of single crystalline silicon layers are formed from the plurality of amorphous silicon layers.

In embodiments, the alignment insulating layer may include a silicon oxide film, a silicon nitride film, a silicon carbide film, a silicon carbonitride film, or a combination thereof. The metal-containing layer may include nickel (Ni), palladium (Pd), titanium (Ti), silver (Ag), gold (Au), aluminum (Al), tin (Sn), antimony (Sb), copper (Cu), cobalt (Co), molybdenum (Mo), ruthenium (Ru), rhodium (Rh), cadmium (Cd), platinum (Pt), or a combination thereof.

In embodiments, during the formation of the plurality of single crystalline silicon layers, in each of the plurality of single crystalline silicon layers, a surface facing a lateral direction substantially orthogonal to the vertical direction may be oriented along a (100) crystal plane.

In embodiments, the method of manufacturing the semiconductor memory device may further include performing a gettering process for removing metal elements remaining in the stack structure after the plurality of single crystalline silicon layers are formed. After the gettering process is performed, from among the plurality of single crystalline silicon layers, a lowest-level single crystalline silicon layer closest to the substrate may include metal impurities. Also, from among the plurality of single crystalline silicon layers, other single crystalline silicon layers except for the lowest-level single crystalline silicon layer may not include metal impurities.

In embodiments, during the formation of the plurality of single crystalline silicon layers, each of the plurality of single crystalline silicon layers may have a first surface facing a first lateral direction substantially orthogonal to the vertical direction, a second surface facing a second lateral direction substantially orthogonal to each of the vertical direction and the first lateral direction, and a third surface facing the vertical direction, and each of the first surface, the second surface, and the third surface may be oriented along a (100) crystal plane. In embodiments, the substrate may include a single-crystalline silicon substrate. In the single-crystalline silicon substrate, surfaces facing the vertical direction and the first lateral direction may be oriented along a (110) crystal plane, and a surface facing the second lateral direction may be oriented along a (100) crystal plane.

In embodiments, the amorphous insulating film may include a silicon oxide film, a silicon nitride film, a silicon oxynitride film, or a combination thereof. During the formation of the stack structure, the stack structure may be formed apart from the substrate in the vertical direction to contact the amorphous insulating film.

In embodiments, the method of manufacturing the semiconductor memory device may further include removing the plurality of sacrificial layers after the plurality of single crystalline silicon layers are formed.

In embodiments, the method of manufacturing the semiconductor memory device may further include forming a plurality of active regions from the plurality of single crystalline silicon layers, forming a bit line to be connected to one end of each of the plurality of active regions, and forming a plurality of capacitors, each capacitor being configured to be connected to another end of a corresponding one of the plurality of active regions.

### BRIEF DESCRIPTION OF THE DRAWINGS

Embodiments will be more clearly understood from the following detailed description taken in conjunction with the accompanying drawings in which:

FIGS. 1A to 1G are cross-sectional views of a process sequence of a method of manufacturing a semiconductor memory device, according to embodiments;

FIGS. 2A to 2G are cross-sectional views of a process sequence of a method of manufacturing a semiconductor memory device, according to embodiments;

FIG. 3 is a block diagram of a semiconductor memory device according to embodiments;

FIGS. 4, 5A, 5B, and 6 are plan views of a semiconductor memory device according to embodiments;

FIG. 5A is a cross-sectional view taken along line X1-X1′ of FIG. 4;

FIG. 5B is a cross-sectional view taken along line Y1-Y1′ of FIG. 4;

FIG. 6 is an enlarged cross-sectional view of a partial region denoted by “EX1” in FIG. 5A;

FIG. 7 is a cross-sectional view of a semiconductor memory device according to embodiments; and

FIGS. 8 to 27 are diagrams illustrating a method of manufacturing a semiconductor memory device, according to embodiments, wherein FIGS. 8, 9, 10, 11, 12, 13, 14, 15A, 16, 17A, 18, and 19A are each a cross-sectional view of a partial region corresponding to a cross-section taken along line X1-X1′ of FIG. 4, according to a process sequence, FIGS. 15B and 17B are cross-sectional views of a partial region corresponding to a cross-section taken along line Y1-Y1′ of FIG. 4, according to a process sequence, FIG. 19B is an enlarged cross-sectional view of a partial region “EXB” of FIG. 19A, and FIGS. 20, 21, 22, 23, 24, 25, 26, and 27 are each an enlarged cross-sectional view of a region corresponding to a partial region “EX1” of FIG. 5A, according to a process sequence.

### DETAILED DESCRIPTION

Hereinafter, embodiments will be described in detail with reference to the accompanying drawings. The same reference numerals are used to denote the same elements in the drawings, and repeated descriptions thereof will be omitted.

As used herein, it will be understood that, although the terms first, second, etc. may be used herein to describe various elements, these elements should not be limited by these terms. These terms are only used to distinguish one element from another. Thus, a first element could be termed a second element, and, similarly, a second element could be termed a first element, without departing from the scope of the inventive concept.

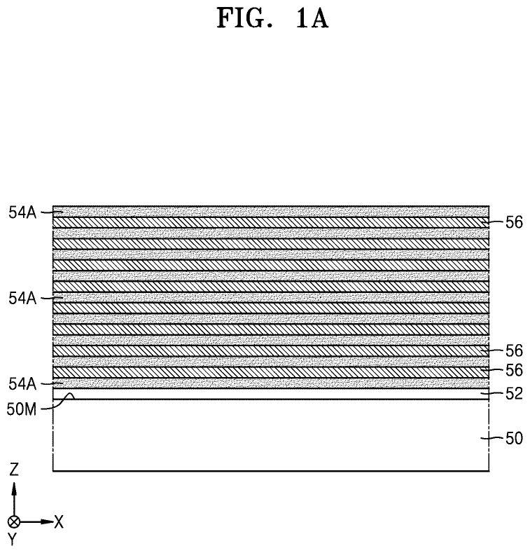

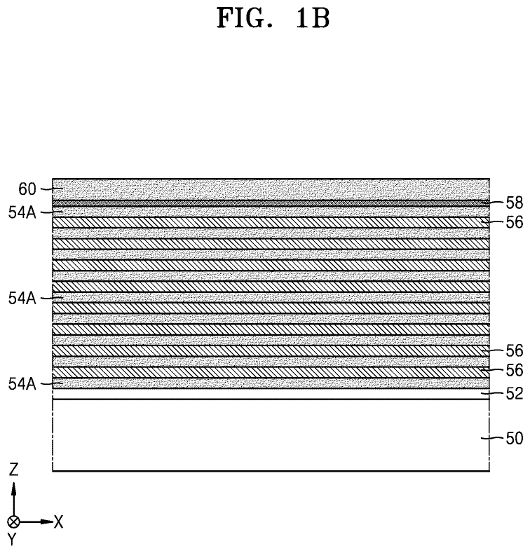

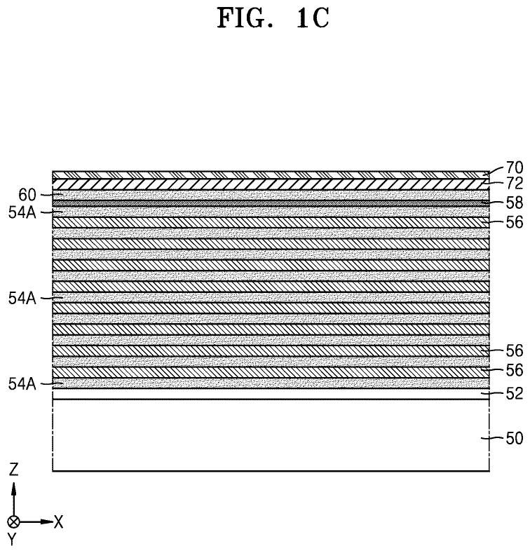

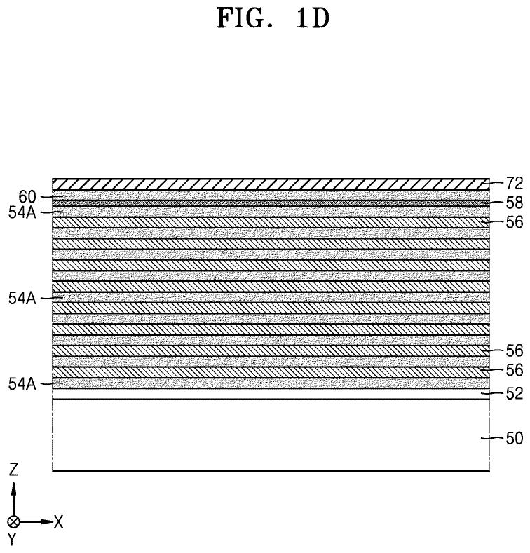

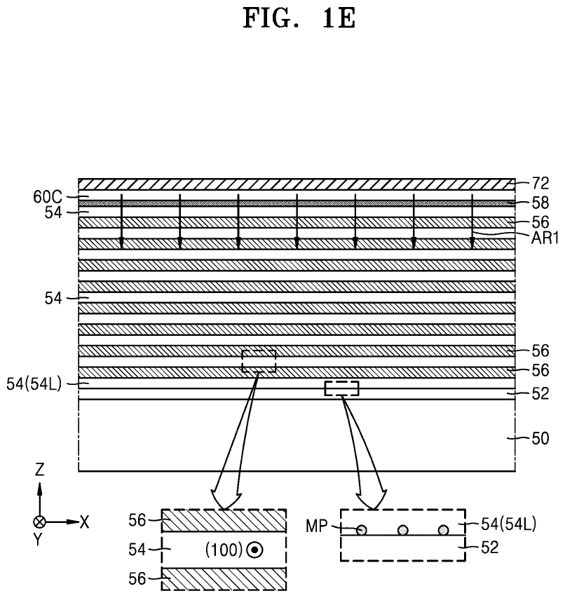

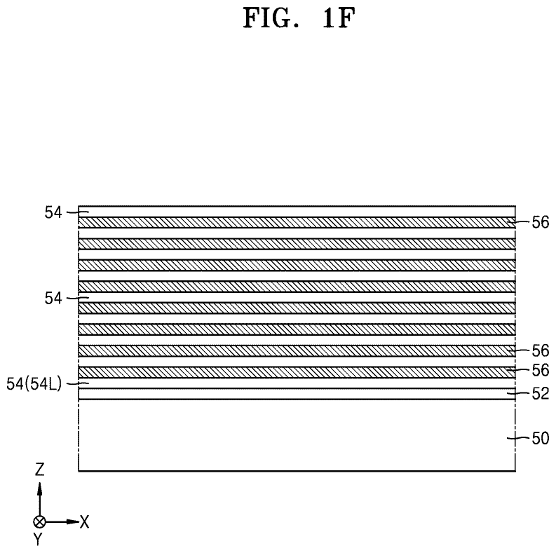

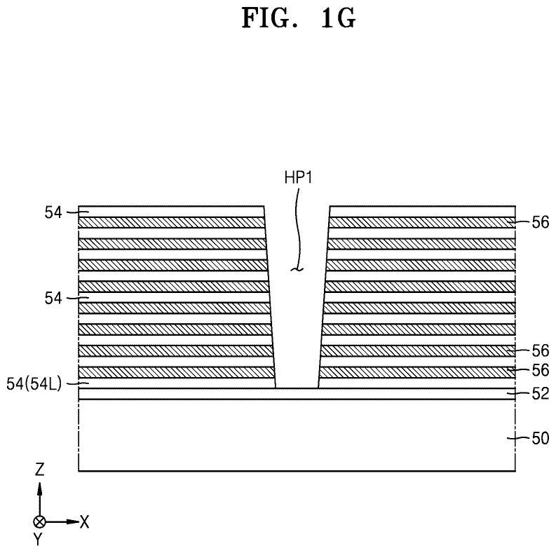

FIGS. 1A to 1G are cross-sectional views of a process sequence of a method of manufacturing a semiconductor memory device, according to embodiments.

Referring to FIG. 1A, an amorphous insulating film 52 may be formed on a main surface 50M of a substrate 50, and a stack structure in which a plurality of amorphous silicon layers 54A and a plurality of sacrificial layers 56 are alternately stacked one-by one in a vertical direction (Z direction) may be formed on the amorphous insulating film 52. The stack structure may be formed apart from the substrate 50 in the vertical direction (Z direction) to contact the amorphous insulating film 52.

In embodiments, the substrate 50 may include a single-crystalline silicon substrate. In the single-crystalline silicon substrate, surfaces facing the vertical direction (Z direction) and a first lateral direction (X direction) orthogonal to the vertical direction (Z direction) may be oriented along a (110) crystal plane, and a surface facing a second lateral direction (Y direction) orthogonal to each of the vertical direction (Z direction) and the first lateral direction (X direction) may be oriented along a (100) crystal plane.

In embodiments, the amorphous insulating film 52 may include a silicon oxide film, a silicon nitride film, a silicon oxynitride film, or a combination thereof, without being limited thereto. The amorphous insulating film 52 may be formed by using a chemical vapor deposition (CVD) process.

The plurality of sacrificial layers 56 may include a material having an etch selectivity with respect to the plurality of amorphous silicon layers 54A. In embodiments, the plurality of sacrificial layers 56 may include an undoped SiGe layer, a SiGe layer doped with carbon (C), a SiGe layer doped with phosphorus (P), a silicon (Si) layer doped with carbon (C), or a Si layer doped with phosphorus (P), without being limited thereto.

A thickness in the vertical direction (Z direction) of each of the plurality of amorphous silicon layers 54A and the plurality of sacrificial layers 56 may be variously determined. For example, in the vertical direction (Z direction), a thickness of each of the plurality of amorphous silicon layers 54A may be less or greater than a thickness of each of the plurality of sacrificial layers 56. Alternatively, in the vertical direction (Z direction), a thickness of each of the plurality of amorphous silicon layers 54A may be equal to or similar to a thickness of each of the plurality of sacrificial layers 56.

A selective epitaxial growth process may not be used to form the plurality of amorphous silicon layers 54A and the plurality of sacrificial layers 56. For example, the plurality of amorphous silicon layers 54A and the plurality of sacrificial layers 56 may be formed by using a CVD process or an atomic layer deposition (ALD) process, without being limited thereto.

An amorphous silicon layer 54A at a highest level, from among the plurality of amorphous silicon layers 54A, may be exposed at an uppermost surface of the stack structure including the plurality of amorphous silicon layers 54A and the plurality of sacrificial layers 56.

Referring to FIG. 1B, an alignment insulating layer 58 may be formed on the stack structure including the plurality of amorphous silicon layers 54A and the plurality of sacrificial layers 56, and a sacrificial amorphous silicon layer 60 may be formed on the alignment insulating layer 58.

The alignment insulating layer 58 may include a silicon oxide film, a silicon nitride film, a silicon carbide film, a silicon carbonitride film, or a combination thereof. The alignment insulating layer 58 may be formed by using a CVD process or an ALD process. In embodiments, when the alignment insulating layer 58 includes a silicon oxide film, the alignment insulating layer 58 may be formed by thermally oxidizing an exposed portion of the amorphous silicon layer 54A at the highest level, which is exposed at the uppermost surface of the stack structure including the plurality of amorphous silicon layers 54A and the plurality of sacrificial layers 56. The alignment insulating layer 58 may have a constant thickness in the vertical direction (Z direction) on the substrate 50. Because the alignment insulating layer 58 has the constant thickness, the metal elements may be uniformly diffused at all positions on the substrate 50 during a metal element diffusion process, which is required for a metal-induced crystallization process described below with reference to FIG. 1E.

In embodiments, the sacrificial amorphous silicon layer 60 may include the same material as the plurality of amorphous silicon layers 54A. The sacrificial amorphous silicon layer 60 may be formed by using the same process as the process of forming the plurality of amorphous silicon layers 54A. In the vertical direction (Z direction), a thickness of the sacrificial amorphous silicon layer 60 may be greater than a thickness of each of the plurality of amorphous silicon layers 54A.

Referring to FIG. 1C, in the resultant structure of FIG. 1B, a metal-containing layer 70 may be formed to cover a top surface of the sacrificial amorphous silicon layer 60, and then the obtained resultant structure may be thermally treated, and thus, a portion of the sacrificial amorphous silicon layer 60 may be transformed into a metal silicide layer 72.

In embodiments, the metal-containing layer 70 may include a metal layer formed by using an ALD process or a metal layer formed by using a sputtering process. In embodiments, the metal-containing layer 70 may include only a metal. In embodiments, the metal-containing layer 70 may include a metal-containing insulating film. The metal-containing insulating film may include a metal-containing oxide film. A metal content on a surface of the metal-containing insulating film may be selected in a range of about 10¹¹ atoms/cm² to about 10¹⁵ atoms/cm², without being limited thereto.

In embodiments, metal elements included in the metal-containing layer 70 may include nickel (Ni), palladium (Pd), titanium (Ti), silver (Ag), gold (Au), aluminum (Al), tin (Sn), antimony (Sb), copper (Cu), cobalt (Co), molybdenum (Mo), ruthenium (Ru), rhodium (Rh), cadmium (Cd), platinum (Pt), or a combination thereof. The metal silicide layer 72 may include the same type of metal elements as those included in the metal-containing layer 70. For example, the metal silicide layer 72 may include nickel (Ni), palladium (Pd), titanium (Ti), silver (Ag), gold (Au), aluminum (Al), tin (Sn), antimony (Sb), copper (Cu), cobalt (Co), molybdenum (Mo), ruthenium (Ru), rhodium (Rh), cadmium (Cd), platinum (Pt), or a combination thereof.

Referring to FIG. 1D, the metal-containing layer 70 may be removed from the resultant structure of FIG. 1C to expose a top surface of the metal silicide layer 72. In embodiments, the metal-containing layer 70 may be removed by using a stripping process, without being limited thereto.

Referring to FIG. 1E, a metal-induced crystallization process for crystallizing the plurality of amorphous silicon layers 54A may be performed by using the metal silicide layer 72 and the alignment insulating layer 58. To perform the metal-induced crystallization process, the resultant structure of FIG. 1D, in which the metal silicide layer 72 is exposed, may be thermally treated. During the metal-induced crystallization process, metal elements diffused from the metal silicide layer 72 may pass through the sacrificial amorphous silicon layer 60 and the alignment insulating layer 58 and diffuse toward the substrate 50 while passing through the plurality of amorphous silicon layers 54A in the vertical direction (Z direction) as indicated by a plurality of arrows AR1. Accordingly, as indicated by the plurality of arrows AR1, directions in which the metal elements are diffused may be uniformly aligned in a direction toward the substrate 50. While the metal elements are passing through the sacrificial amorphous silicon layer (refer to 60 in FIG. 1D) and the plurality of amorphous silicon layers (refer to 54A in FIG. 1D) in the directions of the plurality of arrows AR1, the sacrificial amorphous silicon layer 60 and the plurality of amorphous silicon layers 54A may be sequentially crystallized in a direction toward the substrate 50. As a result, a sacrificial single crystalline silicon layer 60C may be obtained from the sacrificial amorphous silicon layer 60, and a plurality of single crystalline silicon layers 54 may be obtained from the plurality of amorphous silicon layers 54A.

In embodiments, to perform the metal-induced crystallization process, the resultant structure of FIG. 1D may be thermally treated at a temperature of about 300 °C to about 1000 °C, for example, about 500 °C to about 800 °C, but a temperature range of the thermal treatment is not limited thereto.

The plurality of single crystalline silicon layers 54 may be arranged in a line in the vertical direction (Z direction) on the substrate 50 and be arranged apart from one another with the sacrificial layer 56 therebetween in the vertical direction (Z direction). After the plurality of single crystalline silicon layers 54 are formed, in each of the plurality of single crystalline silicon layers 54, a surface facing a lateral direction orthogonal to the vertical direction (Z direction) may be oriented along a (100) crystal plane. In embodiments, each of the plurality of single crystalline silicon layers 54 may have a first surface facing the first lateral direction (X direction) orthogonal to the vertical direction (Z direction), a second surface facing the second lateral direction (Y direction) orthogonal to each of the vertical direction (Z direction) and the first lateral direction (X direction), and a third surface facing the vertical direction (Z direction), and each of the first surface, the second surface, and the third surface may be oriented along a (100) crystal plane.

When the substrate 50 includes a single-crystalline silicon substrate, a surface facing the second lateral direction (Y direction) of each of the plurality of single crystalline silicon layers 54 and a surface facing the second lateral direction (Y direction) of the substrate 50 may be oriented along the same crystal plane, that is, a (100) crystal plane. In contrast, in each of the plurality of single crystalline silicon layers 54, surfaces facing the vertical direction (Z direction) and the first lateral direction (X direction) may be oriented along a (100) crystal plane. Also, surfaces facing the vertical direction (Z direction) and the first lateral direction (X direction) of the substrate 50 may be oriented along a (110) crystal plane.

After the plurality of single crystalline silicon layers 54 are formed by using the metal-induced crystallization process, a gettering process may be performed to remove metal elements remaining in the substrate 50 and the stack structure located thereon. In embodiments, after the gettering process is performed, from among the plurality of single crystalline silicon layers 54, a lowest-level single crystalline silicon layer 54L that is closest to the substrate 50 may include metal impurities MP. From among the plurality of single crystalline silicon layers 54, other single crystalline silicon layers 54 except for the lowest-level single crystalline silicon layer 54L may not include metal impurities. The metal impurities MP may include metal elements remaining without being removed after the gettering process, which are some of the metal elements diffused from the metal silicide layer 72 through the alignment insulating layer 58 toward the substrate 50. The lowest-level single crystalline silicon layer 54L may be spaced apart from the substrate 50 with the amorphous insulating film 52 therebetween in the vertical direction (Z direction). The metal impurities MP may include nickel (Ni), palladium (Pd), titanium (Ti), silver (Ag), gold (Au), aluminum (Al), tin (Sn), antimony (Sb), copper (Cu), cobalt (Co), molybdenum (Mo), ruthenium (Ru), rhodium (Rh), cadmium (Cd), platinum (Pt), or a combination thereof.

In embodiments, in the lowest-level single crystalline silicon layer 54L, a content of the metal impurities MP may be in a range of greater than 0 ppm and not more than 500 ppm, for example, a range of greater than 0 ppm and not more than 200 ppm, without being limited thereto.

After the plurality of single crystalline silicon layers 54 are formed, the amorphous insulating film 52 may remain between the substrate 50 and the lowest-level single crystalline silicon layer 54L. A top surface of the amorphous insulating film 52 may be in contact with a bottom surface of the lowest-level single crystalline silicon layer 54L.

Referring to FIG. 1F, the metal silicide layer 72, the sacrificial single crystalline silicon layer 60C, and the alignment insulating layer 58 may be removed from the resultant structure of FIG. 1E to expose a top surface of an uppermost one of the plurality of single crystalline silicon layers 54.

The metal silicide layer 72, the sacrificial single crystalline silicon layer 60C, and the alignment insulating layer 58 may be removed by using a chemical mechanical polishing (CMP) process and a wet cleaning process, without being limited thereto. After the metal silicide layer 72, the sacrificial single crystalline silicon layer 60C, and the alignment insulating layer 58 are removed, the stack structure including the plurality of single crystalline silicon layers 54 and the plurality of sacrificial layers 56 may remain on the amorphous insulating film 52.

Referring to FIG. 1G, in the resultant structure of FIG. 1F, a portion of the stack structure including the plurality of single crystalline silicon layers 54 and the plurality of sacrificial layers 56 may be removed by etching, and thus, a hole HP1 may be formed to pass through the stack structure in the vertical direction (Z direction).

In a view from above, the hole HP1 may have various shapes. For example, in a view from above, the hole HP1 may have various shapes, such as a circular shape, an elliptical shape, a tetragonal shape, and a line shape extending lengthwise in the second lateral direction (Y direction). As used herein, a view from above may refer to a view from an X-Y plane in the accompanying drawings.

Afterwards, various processes, such as a process of processing the plurality of single crystalline silicon layers 54 through the hole HP1 and a process of replacing the plurality of sacrificial layers 56 with another material layer, may be performed, and thus, a semiconductor memory device having a desired final structure may be manufactured. The semiconductor memory device manufactured in the above-described manner may include the resultant structure obtained by processing each of the plurality of single crystalline silicon layers 54. The resultant structures, which are obtained by processing the plurality of single crystalline silicon layers 54 and remain in the semiconductor memory device, may have structural characteristics described above with respect to the plurality of single crystalline silicon layers 54.

According to the method of manufacturing the semiconductor memory device, which has been described with reference to FIGS. 1A to 1G, a selective epitaxial growth process may not be used to form the plurality of single crystalline silicon layers 54 on the substrate 50. Thus, when the semiconductor memory device is manufactured, a problem of a limited degree of freedom for increasing the integration density of the semiconductor memory device and/or a problem of increased process cost due to a selective epitaxial growth process may be minimized. In addition, the alignment insulating layer 58 may be used to perform the metal-induced crystallization process for forming the plurality of single crystalline silicon layers 54. Accordingly, when the metal elements are diffused from the metal silicide layer 72 through the alignment insulating layer 58 into the plurality of amorphous silicon layers 54A, directions in which the metal elements are diffused may be uniformly aligned, and thus, the metal elements may pass through the plurality of amorphous silicon layers 54A in the vertical direction (Z direction) toward the substrate 50. As a result, the plurality of single crystalline silicon layers 54 may be obtained, and respective surfaces of the plurality of single crystalline silicon layers 54 may be controlled to be oriented along a single (100) crystal plane. Therefore, in the semiconductor memory device including a plurality of memory cells including a plurality of active regions obtained from the plurality of single crystalline silicon layers 54, variations in electrical characteristics between the plurality of memory cells may be minimized, and the electrical characteristics of the semiconductor memory device including the plurality of active regions may improve.

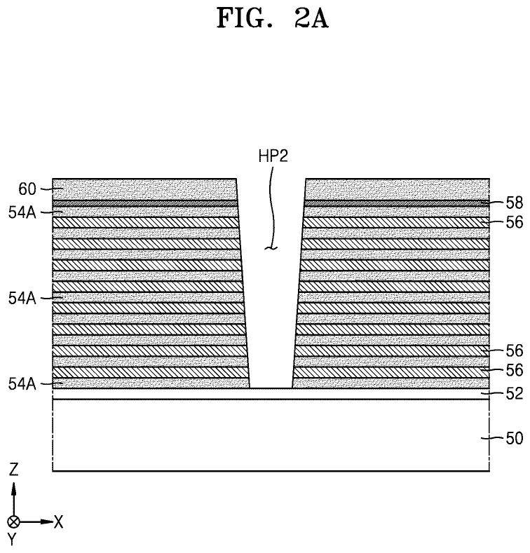

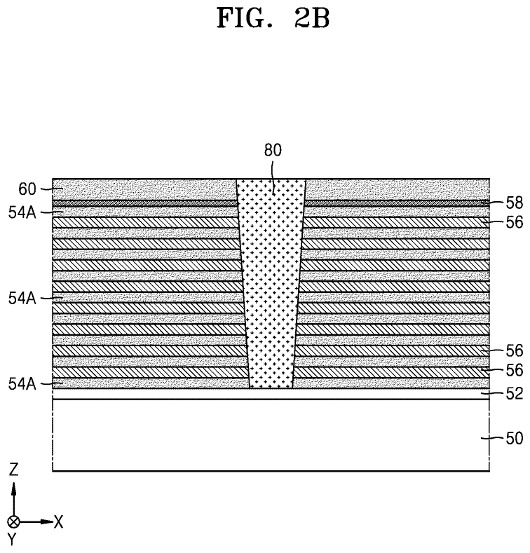

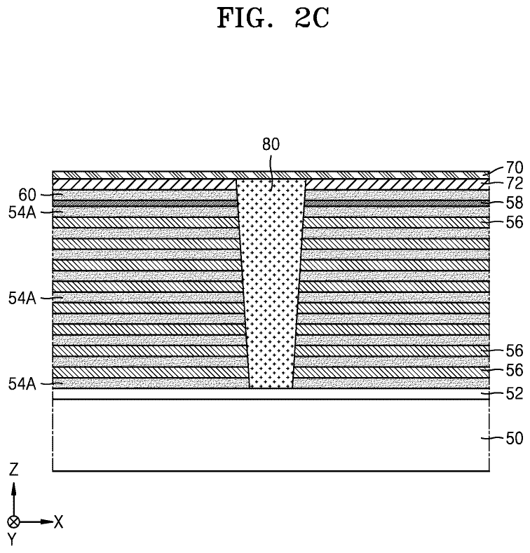

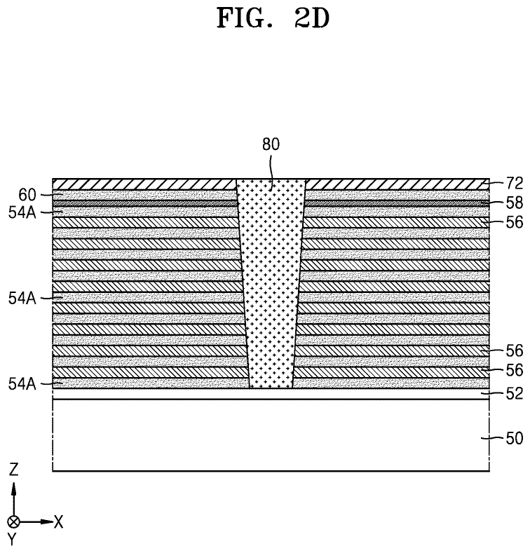

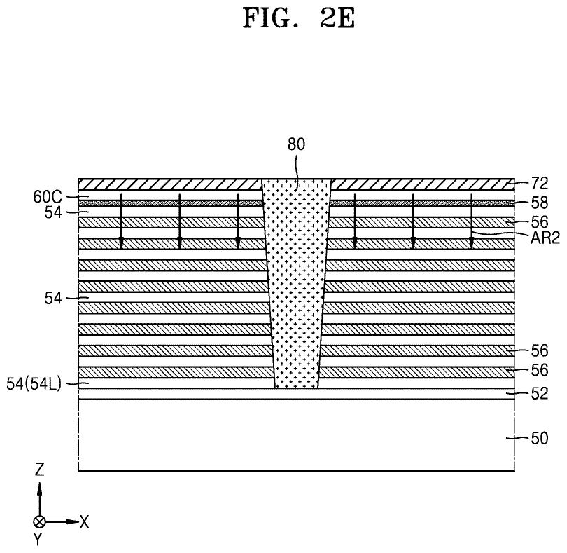

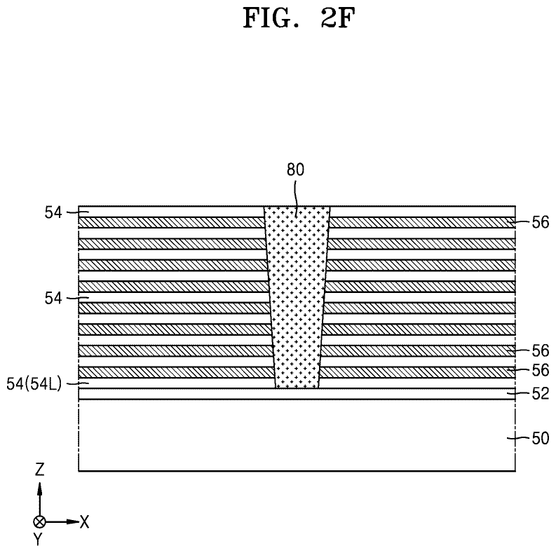

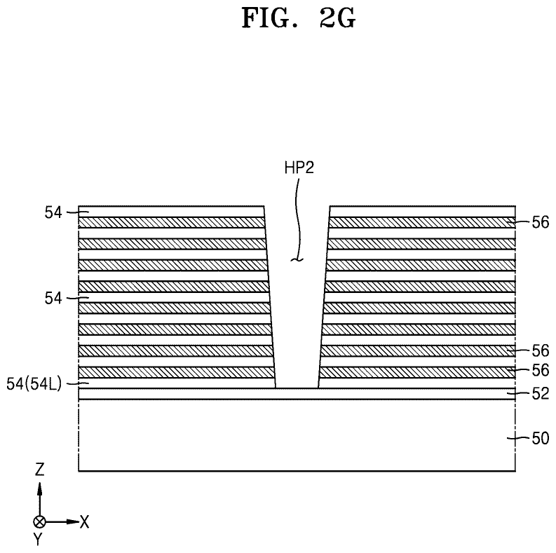

FIGS. 2A to 2G are cross-sectional views of a process sequence of a method of manufacturing a semiconductor memory device, according to embodiments. In FIGS. 2A to 2G, the same reference numerals are used to denote the same elements as in FIGS. 1A to 1G, and thus, repeated descriptions thereof are omitted.

Referring to FIG. 2A, the processes described with reference to FIGS. 1A and 1B may be performed. Thereafter, in the resultant structure of FIG. 1B, a portion of each of a sacrificial amorphous silicon layer 60, an alignment insulating layer 58, and a stack structure including a plurality of amorphous silicon layers 54A and a plurality of sacrificial layers 56 may be etched, and thus, a hole HP2 may be formed to pass through the sacrificial amorphous silicon layer 60, the alignment insulating layer 58, and the stack structure in a vertical direction (Z direction). In a view from above, the hole HP2 may have various shapes. For instance, in a view from above, the hole HP2 may have various shapes, such as a circular shape, an elliptical shape, a tetragonal shape, and a line shape extending lengthwise in a second lateral direction (Y direction).

Referring to FIG. 2B, a sacrificial plug 80 filling the hole HP2 may be formed in the resultant structure of FIG. 2A. After the sacrificial plug 80 is formed, a top surface of each of the sacrificial plug 80 and the sacrificial amorphous silicon layer 60 may be exposed.

The sacrificial plug 80 may include a material having an etch selectivity with respect to each of the sacrificial amorphous silicon layer 60, the alignment insulating layer 58, the plurality of amorphous silicon layers 54A, and the plurality of sacrificial layers 56. In embodiments, the sacrificial plug 80 may include a silicon oxide film, a silicon nitride film, a tungsten film, titanium nitride film, or a combination thereof, without being limited thereto.

Referring to FIG. 2C, in the resultant structure of FIG. 2B, a metal-containing layer 70 may be formed to cover the exposed top surface of each of the sacrificial plug 80 and the sacrificial amorphous silicon layer 60, and then the obtained resultant structure may be thermally treated, and thus, a portion of the sacrificial amorphous silicon layer 60 may be transformed into a metal silicide layer 72.

Referring to FIG. 2D, the metal-containing layer 70 may be removed from the resultant structure of FIG. 2C to expose the top surface of the metal silicide layer 72.

Referring to FIG. 2E, a metal-induced crystallization process for crystallizing a plurality of amorphous silicon layers 54A may be performed by using the metal silicide layer 72 and the alignment insulating layer 58. To perform the metal-induced crystallization process, the resultant structure of FIG. 2D, in which the metal silicide layer 72 is exposed, may be thermally treated. During the metal-induced crystallization process, metal elements diffused from the metal silicide layer 72 may pass through the sacrificial amorphous silicon layer 60 and the alignment insulating layer 58 and diffuse toward a substrate 50 while passing through the plurality of amorphous silicon layers 54A in the vertical direction (Z direction). After passing through the alignment insulating layer 58, the metal elements may pass through the plurality of amorphous silicon layers 54A in the vertical direction (Z direction). Thus, directions in which the metal elements are diffused may be uniformly aligned in a direction toward the substrate 50 in FIG. 2E as indicated by a plurality of arrows AR2. While the metal elements are passing through the sacrificial amorphous silicon layer 60 and the plurality of amorphous silicon layers 54A in the directions of the plurality of arrows AR2, the sacrificial amorphous silicon layer 60 and the plurality of amorphous silicon layers 54A may be sequentially crystallized in the direction toward the substrate 54. As a result, a sacrificial single crystalline silicon layer 60C may be obtained from the sacrificial amorphous silicon layer 60, and a plurality of single crystalline silicon layers 54 may be obtained from the plurality of amorphous silicon layers 54A. Details of the metal-induced crystallization process are the same as those described with reference to FIG. 1E.

After the plurality of single crystalline silicon layers 54 are formed by using the metal-induced crystallization process, a gettering process may be performed to remove metal elements remaining in the substrate 50 and the stack structure located thereon. In embodiments, after the gettering process is performed, similarly to that described with reference to FIG. 1E, from among the plurality of single crystalline silicon layers 54, a lowest-level single crystalline silicon layer 54L closest to the substrate 50 may include metal impurities MP. From among the plurality of single crystalline silicon layers 54, other single crystalline silicon layers 54 except for the lowest-level single crystalline silicon layer 54L may not include metal impurities.

Referring to FIG. 2F, by using a method similar to that described with reference to FIG. 1F, the metal silicide layer 72, the sacrificial single crystalline silicon layer 60C, and the alignment insulating layer 58 may be removed from the resultant structure of FIG. 2E, and thus, a top surface of an uppermost one of the plurality of single crystalline silicon layers 54 may be exposed.

During the removal of the metal silicide layer 72, the sacrificial single crystalline silicon layer 60C, and the alignment insulating layer 58, the sacrificial plug 80 may also be partially removed. As a result, after the metal silicide layer 72, the sacrificial single crystalline silicon layer 60C, and the alignment insulating layer 58 are removed, the exposed top surface of the uppermost one of the plurality of single crystalline silicon layers 54 may form a coplanar surface with the top surface of the sacrificial plug 80.

Referring to FIG. 2G, the sacrificial plug 80 may be removed from the resultant structure of FIG. 2F, and thus, a sidewall of each of the plurality of single crystalline silicon layers 54 and the plurality of sacrificial layers 56 may be exposed inside the hole HP2.

Afterwards, various processes, such as a process of processing the plurality of single crystalline silicon layers 54 through the hole HP2 and a process of replacing the plurality of sacrificial layers 56 with another material layer, may be performed, and thus, a semiconductor memory device having a desired final structure may be manufactured.

According to the method of manufacturing the semiconductor memory device described with reference to FIGS. 2A to 2G, similarly to the method of manufacturing the semiconductor memory device, which has been described with reference to FIGS. 1A to 1G, when the metal elements are diffused from the metal silicide layer 72 through the alignment insulating layer 58 into the plurality of amorphous silicon layers 54A, directions in which the metal elements are diffused may be uniformly aligned. Thus, the metal elements may pass through the plurality of amorphous silicon layers 54A in the vertical direction (Z direction) toward the substrate 50. As a result, the plurality of single crystalline silicon layers 54 may be obtained, and respective surfaces of the plurality of single crystalline silicon layers 54 may be controlled to be oriented along a single (100) crystal plane. Therefore, in the semiconductor memory device including a plurality of memory cells including a plurality of active regions obtained from the plurality of single crystalline silicon layers 54, variations in electrical characteristics between the plurality of memory cells may be minimized, and the electrical characteristics of the semiconductor memory device including the plurality of active regions may improve.

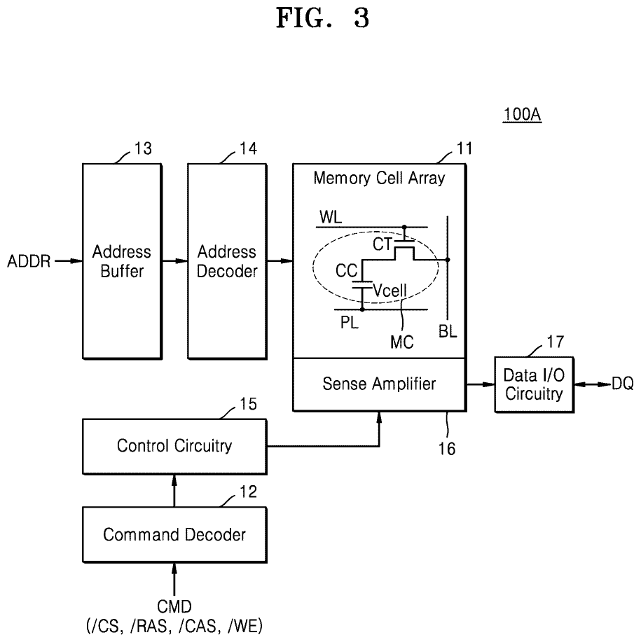

FIG. 3 is a block diagram of a semiconductor memory device 100A according to embodiments.

Referring to FIG. 3, the semiconductor memory device 100A may include a memory cell array 11, a command decoder 12, an address buffer 13, an address decoder 14, a control circuitry 15, a sense amplifier 16, and a data input/output (I/O) circuitry 17.

The memory cell array 11 may include a plurality of memory cells MC. The memory cell array 11 may include a plurality of word lines WL, a plurality of bit lines BL, and a plurality of plate electrodes PL, which are connected to the memory cell MC. The memory cell array 11 may include dynamic random access memory (DRAM) configured to sense, as data, a cell voltage Vcell stored in the memory cell MC.

The semiconductor memory device 100A may receive and output data DQ from and to an external device, in response to a command CMD and an address ADDR, which are received from the external device (e.g., a central processing unit (CPU) or a memory controller).

Each of the plurality of memory cells MC may include a cell transistor CT and a cell capacitor CC. A gate of the cell transistor CT may be connected to the word line WL. A first terminal of the cell transistor CT may be connected to the bit line BL. A second terminal of the cell transistor CT may be connected to a first terminal of the cell capacitor CC. A second terminal of the cell capacitor CC may be connected to the plate electrode PL. The memory cell MC may store, in the cell capacitor CC, a cell voltage Vcell having a magnitude that specifies data.

The command decoder 12 may determine an input command CMD by referring to a chip select signal /CS, a row address strobe signal /RAS, a column address strobe signal /CAS, and a write enable signal /WE, which are applied from the external device. The command decoder 12 may generate control signals corresponding to the command CMD. The command CMD may include an active command, a read command, a write command, and a precharge command.

The address buffer 13 may receive an address ADDR from the external device. The address ADDR may include a word line address for addressing some of the plurality of word lines WL connected to the memory cell array 11, a bit line address for addressing some of the plurality of bit lines BL connected to the memory cell array 11, and a plate line address for addressing some of the plurality of plate electrodes PL connected to the memory cell array 11. The address buffer 13 may transmit each of the word line address, the bit line address, and the plate line address to the address decoder 14.

The address decoder 14 may include a word line decoder, a bit line decoder, and a plate line decoder, which are respectively configured to select the word line WL, the bit line BL, and the plate electrode PL of the memory cell MC to be accessed, in response to the received address ADDR. The word line decoder may decode the word line address and activate the word line WL of the memory cell MC corresponding to the word line address. The bit line decoder may decode the bit line address and provide a bit line select signal BLS for selecting the bit line BL of the memory cell MC corresponding to the bit line address. The plate line decoder may decode the plate line address and provide a plate line select signal PLS for selecting the plate electrode PL of the memory cell MC corresponding to the plate line address.

The control circuit 15 may control the sense amplifier 16 via the control of the command decoder 12. The control circuit 15 may control an operation of the sense amplifier 16 to detect a cell voltage Vcell of the memory cell MC. The control circuit 15 may control the sense amplifier 16 to perform a precharge operation, a charge sharing operation, and a sense operation.

The sense amplifier 16 may sense, as data, charges stored in the memory cell MC. Also, the sense amplifier 16 may transmit detected data DQ to the data I/O circuit 17 such that the detected data DQ is output to the outside of the semiconductor memory device 100A.

The data I/O circuit 17 may receive data DQ to be written to the memory cell MC from the outside and transmit the data DQ to the memory cell array 11. The data I/O circuit 17 may externally output bit data detected by the sense amplifier 16 as read data.

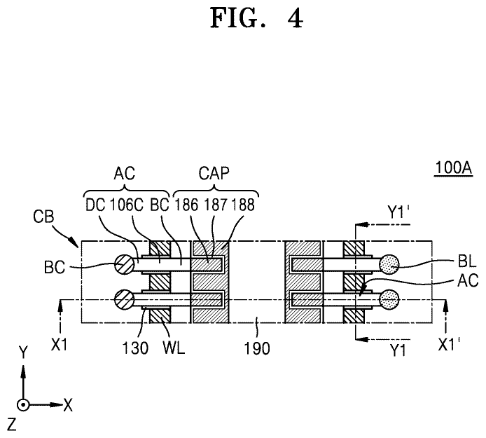

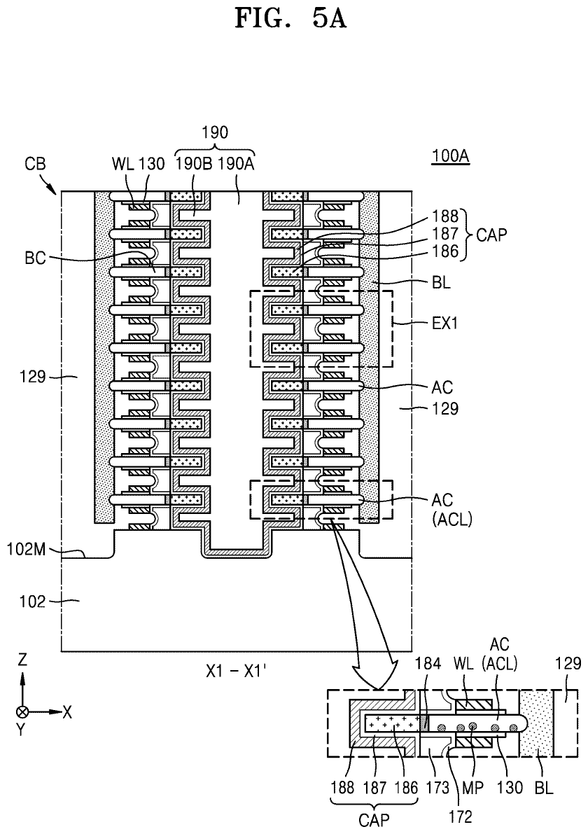

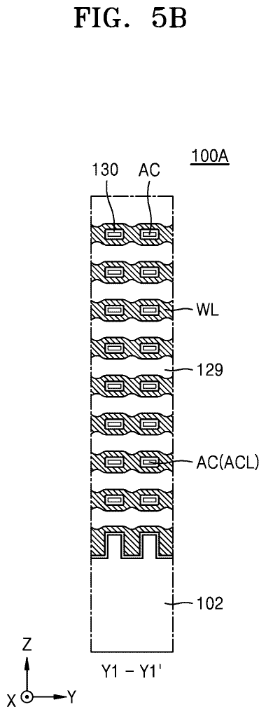

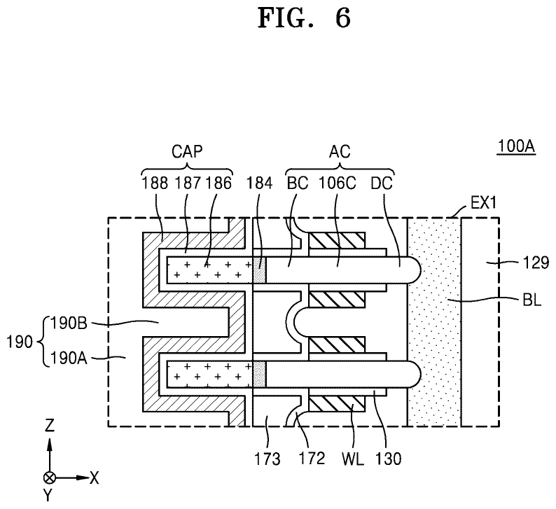

FIGS. 4, 5A, 5B, and 6 are diagrams of a semiconductor memory device 100A according to embodiments. More specifically, FIG. 4 is a plan view of the semiconductor memory device 100A according to the embodiments. FIG. 5A is a cross-sectional view taken along line X1-X1′ of FIG. 4. FIG. 5B is a cross-sectional view taken along line Y1-Y1′ of FIG. 4. FIG. 6 is an enlarged cross-sectional view of a partial region denoted by “EX1” in FIG. 5A. Components of the semiconductor memory device 100A described below with reference to FIGS. 4, 5A, 5B, and 6 may constitute a portion of the memory cell array 11 described with reference to FIG. 3.

Referring to FIGS. 4, 5A, 5B, and 6, the semiconductor memory device 100A may include a memory cell block CB including a plurality of memory cells, which are repeatedly arranged on a substrate 102 in a first lateral direction (X direction), a second lateral direction (Y direction), and a vertical direction (Z direction). The first lateral direction (X direction) and the second lateral direction (Y direction) may be parallel to a main surface 102M of the substrate 102 and be orthogonal to one another, and the vertical direction (Z direction) may be perpendicular to the main surface 102M of the substrate 102.

The substrate 102 may include a single-crystalline silicon substrate. In the single-crystalline silicon substrate, surfaces facing the vertical direction (Z direction) and the first lateral direction (X direction) orthogonal to the vertical direction (Z direction) may be oriented along a (110) crystal plane, and a surface facing the second lateral direction (Y direction) orthogonal to each of the vertical direction (Z direction) and the first lateral direction (X direction) may be oriented along a (100) crystal plane.

The memory cell block CB may include a plurality of active regions AC, which are repeatedly arranged in the first lateral direction (X direction) and the second lateral direction (Y direction) at each of a plurality of vertical levels that are apart from the substrate 102 in the vertical direction (Z direction). As shown in FIG. 5A, the plurality of active regions AC included in the memory cell block CB may include a plurality of active regions AC, which are arranged in a line in the vertical direction (Z direction) on the substrate 102 and overlap one another in the vertical direction (Z direction).

Each of the plurality of active regions AC may include a single crystalline silicon layer. The plurality of active regions AC may be obtained from a plurality of single crystalline silicon layers 54, which are obtained by using the method of manufacturing the semiconductor memory device, which has been described with reference to FIGS. 1A to 1G, or the method of manufacturing the semiconductor memory device, which has been described with reference to FIGS. 2A to 2G. As used herein, the active region AC may be referred to as a single crystalline silicon layer.

Each of the plurality of active regions AC may have a first surface facing the first lateral direction (X direction) that is orthogonal to the vertical direction (Z direction), a second surface facing the second lateral direction (Y direction) that is orthogonal to each of the vertical direction (Z direction) and the first lateral direction (X direction), and a third surface facing the vertical direction (Z direction). From among the first surface, the second surface, and the third surface of each of the plurality of active regions AC, at least the second surface facing the second lateral direction (Y direction) may be oriented along a (100) crystal plane. In embodiments, in each of the plurality of active regions AC, each of the first surface, the second surface, and the third surface may be oriented along a (100) crystal plane.

When the substrate 50 includes a single-crystalline silicon substrate, a surface facing the second lateral direction (Y direction) of each of the plurality of active regions AC and a surface facing the second lateral direction (Y direction) of the substrate 102 may be oriented along the same crystal plane, that is, a (100) crystal plane. In contrast, in each of the plurality of active regions AC, surfaces facing the vertical direction (Z direction) and the first lateral direction (X direction) may be oriented along a (100) crystal plane. Also, surfaces facing the vertical direction (Z direction) and the first lateral direction (X direction) of the substrate 102 may be oriented along a (110) crystal plane.

From among the plurality of active regions AC, lowest-level active regions ACL that are closest to the substrate 102 in the vertical direction (Z direction) may include metal impurities MP. Detailed compositions of the metal impurities MP may be the same as those described with reference to FIG. 1E. In the lowest-level active regions ACL, a content of the metal impurities MP may be in a range of greater than 0 ppm and not more than 500 ppm, for example, a range of greater than 0 ppm and not more than 200 ppm, without being limited thereto. From among the plurality of active regions AC, the active regions AC, which are spaced apart from the substrate 102 with the lowest-level active regions ACL therebetween in the vertical direction (Z direction), may not include metal impurities.

As shown in the enlarged view of FIG. 6, each of the plurality of active regions AC may include a channel region 106C and a buried contact BC and a direct contact DC, which are spaced apart from one another with the channel region 106C therebetween in the first lateral direction (X direction). In each of the plurality of active regions AC, the buried contact BC, the channel region 106C, and the direct contact DC may be sequentially arranged to be collinear with one another in the first lateral direction (X direction).

As shown in FIGS. 4, 5A, and 6, the memory cell block CB of the semiconductor memory device 100A may include a plurality of word lines WL, which extend lengthwise in the second lateral direction (Y direction), which is parallel to the main surface 120M of the substrate 102, at each of a plurality of vertical levels that are apart from the substrate 102 in the vertical direction (Z direction). The plurality of word lines WL may be arranged apart from one another in the first lateral direction (X direction), the second lateral direction (Y direction), and the vertical direction (Z direction). Each of the plurality of word lines WL may surround the channel region 106C, which is a local region of a selected one of the plurality of active regions AC included in the memory cell block CB, and extend lengthwise in the second lateral direction (Y direction). As shown in FIG. 5A, the plurality of word lines WL included in the memory cell block CB may include a plurality of word lines WL, which are arranged in a line in the vertical direction (Z direction) on the substrate 102 and overlap one another in the vertical direction (Z direction).

In embodiments, each of the plurality of word lines WL may include a metal, a conductive metal nitride, a metal silicide, doped polysilicon, or a combination thereof. For example, each of the plurality of word lines WL may include titanium (Ti), titanium nitride (TiN), tantalum (Ta), tantalum nitride (TaN), molybdenum (Mo), ruthenium (Ru), tungsten (W), tungsten nitride (WN), cobalt (Co), aluminum (Al), nickel (Ni), titanium silicide (TiSi), titanium silicon nitride (TiSiN), tungsten silicide (WSi), tungsten silicon nitride (WSiN), tantalum silicide (TaSi), tantalum silicon nitride (TaSiN), ruthenium titanium nitride (RuTiN), cobalt silicide (CoSi), nickel silicide (NiSi), doped polysilicon, or a combination thereof, without being limited thereto.

A gate dielectric film 130 may be between the channel region 106C of the active region AC and the word line WL. In the first lateral direction (X direction), a width of each of a plurality of gate dielectric films 130 may be greater than a width of each of the plurality of word lines WL. In embodiments, the gate dielectric film 130 may include a paraelectric material. For example, the gate dielectric film 130 may include silicon oxide, silicon nitride, silicon oxynitride, or a combination thereof. In embodiments, the gate dielectric film 130 may include a high-k dielectric material. The high-k dielectric material may have a dielectric constant of about 10 to about 25. For example, the high-k dielectric material may include hafnium oxide, aluminum oxide, zirconium oxide, or a combination thereof, without being limited thereto. For example, each of the plurality of gate dielectric films 130 may include HfO₂, Al₂O₃, ZrO₂, or a combination thereof, without being limited thereto. In still embodiments, the gate dielectric film 130 may include a combination of a paraelectric material and a high-k dielectric material.

As shown in FIGS. 5A and 6, respective spaces between the plurality of word lines WL arranged in a line in the vertical direction (Z direction) may be filled by an insulating structure 129. The insulating structure 129 may include a silicon oxide film, a silicon nitride film, or a combination thereof.

The memory cell block CB of the semiconductor memory device 100A may include a plurality of bit lines BL that extend lengthwise in the vertical direction (Z direction). Each of the plurality of bit lines BL may pass through the insulating structure 129 on the substrate 102 and extend lengthwise in the vertical direction (Z direction). Each of the plurality of bit lines BL may be connected to one end of each of a plurality of active regions AC overlapping one another in the vertical direction (Z direction), from among the plurality of active regions AC included in the memory cell block CB. Each of the plurality of bit lines BL may be connected to the direct contact DC of a selected one of the plurality of active regions AC.

In embodiments, the direct contact DC included in the active region AC may include a doped silicon layer. For example, the direct contact DC may include a silicon layer doped with an n-type dopant. Each of the plurality of bit lines BL may include a metal, a conductive metal nitride, metal silicide, doped polysilicon, or a combination thereof. For instance, each of the plurality of bit lines BL may include Ti, TiN, Ta, TaN, Mo, Ru, W, WN, Co, Al, Ni, TiSi, TiSiN, WSi, WSiN, TaSi, TaSiN, RuTiN, CoSi, NiSi, doped polysilicon, or a combination thereof, without being limited thereto.

As shown in FIGS. 4, 5A, and 6, the memory cell block CB of the semiconductor memory device 100A may include a plurality of capacitors CAP connected to the plurality of active regions AC. Each of the plurality of capacitors CAP may include a first electrode 186, a dielectric film 187, and a second electrode 188. The first electrode 186 of the capacitor CAP may be connected to the buried contact BC of a selected one of the plurality of active regions AC.

As shown in FIGS. 5A and 6, a metal silicide film 184 may be between the first electrode 186 of the capacitor CAP and the buried contact BC of the active region AC. The metal silicide film 184 may include titanium silicide, tantalum silicide, cobalt silicide, molybdenum silicide, or tungsten silicide, without being limited thereto. The first electrode 186 of the capacitor CAP may be electrically connectable to the buried contact BC of the active region AC through the metal silicide film 184. In embodiments, the metal silicide film 184 may be omitted. In this case, the first electrode 186 of the capacitor CAP may be in contact with the buried contact BC of the active region AC. The second electrode 188 of the capacitor CAP may be spaced apart from the active region AC and cover a surface of the first electrode 186. The dielectric film 187 of the capacitor CAP may be between the first electrode 186 and the second electrode 188.

As shown in FIG. 4, in a view from above, the plurality of capacitors CAP may be adjacent to the plurality of word lines WL and the plurality of active regions AC and be arranged in a line in the second lateral direction (Y direction). As shown in FIGS. 4 and 5A, the bit line BL may be apart from the plurality of capacitors CAP with the plurality of word lines WL therebetween in the first lateral direction (X direction).

In each of the plurality of capacitors CAP, each of the first electrode 186 and the second electrode 188 may include a metal film, a conductive metal oxide film, a conductive metal nitride film, a conductive metal oxynitride film, or a combination thereof. In embodiments, each of the first electrode 186 and the second electrode 188 may include molybdenum (Mo), tungsten (W), ruthenium (Ru), platinum (Pt), iridium (Ir), cobalt (Co), tin (Sn), titanium (Ti), a Ti nitride, a Ti oxide, a Ti oxynitride, niobium (Nb), a Nb nitride, a Nb oxide, a Nb oxynitride, a tungsten (W) nitride, a vanadium (V) nitride, a V oxide, a molybdenum (Mo) nitride, a Mo oxide, a ruthenium (Ru) oxide, a strontium ruthenium (SrRu) oxide, a cobalt (Co) nitride, a Co oxide, a Co oxynitride, a tin (Sn) nitride, a Sn oxide, a Sn oxynitride, or a combination thereof. For example, each of the first electrode 186 and the second electrode 188 may include titanium nitride (TiN), niobium nitride (NbN), cobalt nitride (CoN), tin oxide (SnO₂), or a combination thereof. In embodiments, each of the first electrode 186 and the second electrode 188 may include tantalum nitride (TaN), titanium aluminum nitride (TiAlN), tantalum aluminum nitride (TaAlN), vanadium (V), vanadium nitride (VN), molybdenum (Mo), molybdenum nitride (MoN), tungsten (W), tungsten nitride (WN), ruthenium (Ru), ruthenium oxide (RuO₂), strontium ruthenium oxide (SrRuO₃), iridium (Ir), iridium oxide (IrO₂), platinum (Pt), platinum oxide (PtO), SrRuO₃ (SRO), (Ba,Sr)RuO₃ (BSRO), CaRuO₃ (CRO), (La,Sr)CoO₃ (LSCo), or a combination thereof. However, a constituent material of each of the first electrode 186 and the second electrode 188 is not limited to the examples described above.

The dielectric film 187 may include a silicon oxide film, a high-k dielectric film, or a combination thereof. In embodiments, the dielectric film 187 may include a metal oxide including at least one metal selected from hafnium (Hf), zirconium (Zr), aluminum (Al), niobium (Nb), cerium (Ce), lanthanum (La), tantalum (Ta), and titanium (Ti). In embodiments, the dielectric film 187 may have a single film structure including a single high-k dielectric film. In embodiments, the dielectric film 187 may have a multilayered film structure including a plurality of high-k dielectric films sequentially stacked on the first electrode 186. The high-k dielectric film may include a HfO₂ film, a ZrO₂ film, a Al₂O₃ film, a Y₂O₃ film, a Sc₂O₃ film, a La₂O₃ film, a Ta₂O₅ film, a Nb₂O₅ film, a CeO₂ film, a TiO₂ film, a GeO₂ film, a SrTiO₃ film, a BaSrTiO₃ film, or a combination thereof, without being limited thereto. In embodiments, the dielectric film 187 may include an oxide of at least one metal selected from Ti, Nb, Ta, Sn, and Mo or an oxynitride of at least one metal selected from Ti, Nb, Ta, Sn, and Mo. For example, the dielectric film 187 may include a Ti oxide, a Ti oxynitride, a Nb oxide, a Nb oxynitride, a Ta oxide, a Ta oxynitride, a Sn oxide, a Sn oxynitride, a Mo oxide, a Mo oxynitride, or a combination thereof. In still embodiments, the dielectric film 187 may include a ferroelectric film, which includes at least one oxide selected from hafnium (Hf), silicon (Si), aluminum (Al), zirconium (Zr), yttrium (Y), lanthanum (La), gadolinium (Gd), and strontium (Sr). The ferroelectric film may include a hafnium-based oxide, for example, hafnium oxide (HfO), hafnium zirconium oxide (HZO), hafnium titanium oxide, or hafnium silicon oxide. The ferroelectric film may further include a dopant as needed. The dopant may include at least one element selected from silicon (Si), aluminum (Al), zirconium (Zr), yttrium (Y), lanthanum (La), gadolinium (Gd), scandium (Sc), strontium (Sr), magnesium (Mg), and barium (Ba), without being limited thereto.

The semiconductor memory device 100A may include an insulating liner 172 surrounding the buried contact BC and a buried insulating film 173 covering the insulating liner 172. The insulating liner 172 may cover a sidewall of the word line WL. In embodiments, the insulating liner 172 may include silicon oxide, and the buried insulating film 173 may include silicon nitride, without being limited thereto.

As shown in FIGS. 4 and 5A, the memory cell block CB of the semiconductor memory device 100A may further include a plate electrode 190. The plate electrode 190 may correspond to the plate electrode PL described with reference to FIG. 3. As shown in FIG. 5A, the plate electrode 190 may include a center portion 190A and a plurality of finger portions 190B. The center portion 190A may extend lengthwise in the vertical direction (Z direction) on the substrate 102. The plurality of finger portions 190B may protrude from the center portion 190A in the first lateral direction (X direction). Each of the plurality of finger portions 190B of the plate electrode 190 may overlap the first electrode 186 of the capacitor CAP in the vertical direction (Z direction). The plurality of finger portions 190B of the plate electrode 190 may be spaced apart from the first electrode 186 of the capacitor CAP with the dielectric film 187 and the second electrode 188 of the capacitor CAP therebetween in the vertical direction (Z direction). A plurality of capacitors CAP located on both sides of one plate electrode 190 in the first lateral direction (X direction) may share the one plate electrode 190. The plate electrode 190 may include a metal film, a conductive metal oxide film, a conductive metal nitride film, a conductive metal oxynitride film, a semiconductor film, or a combination thereof. In embodiments, the plate electrode 190 may include Ti, a Ti nitride, a Ti oxide, a Ti oxynitride, Nb, a Nb nitride, a Nb oxide, a Nb oxynitride, Co, a Co nitride, a Co oxide, a Co oxynitride, Sn, a Sn nitride, a Sn oxide, a Sn oxynitride, silicon germanium (SiGe), or a combination thereof. For example, the plate electrode 190 may include titanium nitride (TiN), niobium nitride (NbN), tantalum nitride (TaN), titanium aluminum nitride (TiAlN), tantalum aluminum nitride (TaAlN), vanadium (V), vanadium nitride (VN), molybdenum (Mo), molybdenum nitride (MoN), tungsten (W), tungsten nitride (WN), ruthenium (Ru), iridium (Ir), platinum (Pt), silicon germanium (SiGe), or a combination thereof, without being limited thereto.

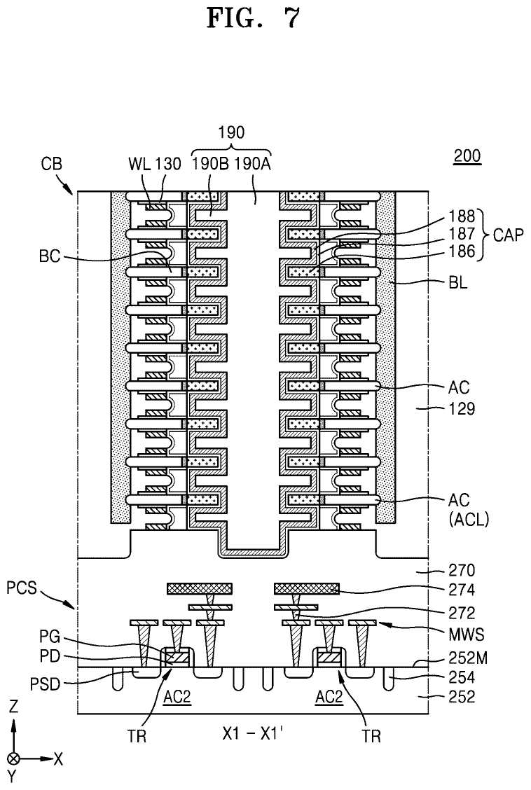

FIG. 7 is a cross-sectional view of a semiconductor memory device 200 according to embodiments. FIG. 7 illustrates a cross-sectional configuration of a portion of the semiconductor memory device 200, which corresponds to a cross-section taken along line X1-X1′ of FIG. 4. In FIG. 7, the same reference numerals are used to denote the same elements as in FIGS. 4, 5A, 5B, and 6, and thus, repeated descriptions thereof are omitted.

Referring to FIG. 7, the semiconductor memory device 200 may substantially have the same configuration as the semiconductor memory device 100A described with reference to FIGS. 4, 5A, 5B, and 6. However, the semiconductor memory device 200 may further include a peripheral circuit structure PCS, which overlaps a memory cell block CB in a vertical direction (Z direction). The semiconductor memory device 200 may have a cell on peripheral circuit (COP) structure in which the memory cell block CB is arranged on the peripheral circuit structure PCS.

The peripheral circuit structure PCS may include a plurality of circuits formed on a substrate 252 and a multilayered wiring structure MWS configured to connect the plurality of circuits to one another or connect the plurality of circuits to a plurality of memory cells included in the memory cell block CB. In the vertical direction (Z direction), the peripheral circuit structure PCS may be between the substrate 252 and the memory cell block CB.

The substrate 252 may include a single-crystalline silicon substrate. In the single-crystalline silicon substrate, surfaces facing the vertical direction (Z direction) and a first lateral direction (X direction) orthogonal to the vertical direction (Z direction) may be oriented along a (110) crystal plane, and a surface facing a second lateral direction (Y direction) orthogonal to each of the vertical direction (Z direction) and the first lateral direction (X direction) may be oriented along a (100) crystal plane.

Active regions AC2 may be defined by device isolation films 254 in the substrate 252. A plurality of transistors TR that constitute the plurality of circuits may be formed on the active regions AC2. Each of the plurality of transistors TR may include a gate dielectric film PD and a gate PG, which are sequentially stacked on the substrate 252, and a plurality of ion implantation regions PSD formed in the active region AC2 on both sides of the gate PS. Each of the plurality of ion implantation regions PSD may constitute a source region or a drain region of the transistor TR.

The multilayered wiring structure MWS included in the peripheral circuit structure PCS may include a plurality of contact plugs 272 and a plurality of conductive lines 274. At least some of the plurality of conductive lines 274 may be electrically connectable to the transistor TR. The plurality of contact plugs 272 may be configured to connect the plurality of transistors TR to some conductive lines 274 selected from the plurality of conductive lines 274. The plurality of transistors TR and the multilayered wiring structure MWS, which are included in the peripheral circuit structure PCS, may be covered by an interlayer insulating film 270. The interlayer insulating film 270 may include a silicon oxide film, a silicon nitride film, a silicon oxynitride film (SiON film), a silicon oxycarbonitride film (SiOCN film), or a combination thereof.

The plurality of transistors TR, the plurality of contact plugs 272, and the plurality of conductive lines 274, which are included in the peripheral circuit structure PCS, may constitute the plurality of circuits. Each of the plurality of transistors TR may be configured to be electrically connectable to the plurality of memory cells included in the memory cell block CB through a plurality of multilayered wiring structures MWS.

According to the semiconductor memory device 100A described with reference to FIGS. 4, 5A, 5B, and 6 and the semiconductor memory device 200 described with reference to FIG. 7, the memory cell block CB may include a plurality of memory cells, which are repeatedly arranged on the substrate 102 or 252 in the first lateral direction (X direction), the second lateral direction (Y direction), and the vertical direction (Z direction). In each of the plurality of active regions AC included in the plurality of memory cells, a surface facing a lateral direction parallel to the main surface 102M or 252M of the substrate 102 or 252 may be oriented along a (100) crystal plane. Each of the plurality of active regions AC may include a single crystalline silicon layer, which is obtained by crystallizing an amorphous silicon layer by using a metal-induced crystallization process. The plurality of active regions AC may provide higher electron mobility than polycrystalline active regions that are not completely crystallized or have partially different crystal planes. Therefore, the electrical characteristics of the semiconductor memory devices 100A and 200 including the plurality of active regions AC may improve.

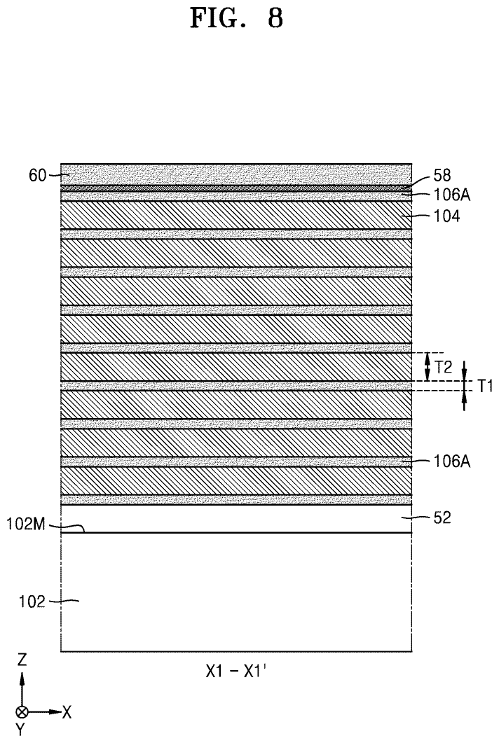

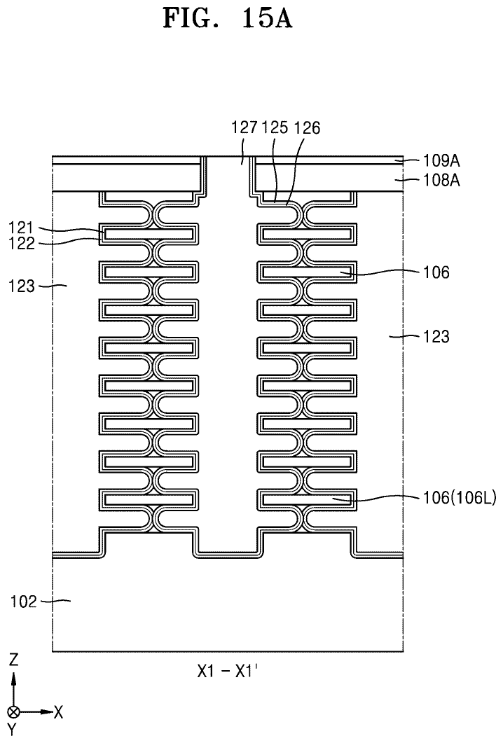

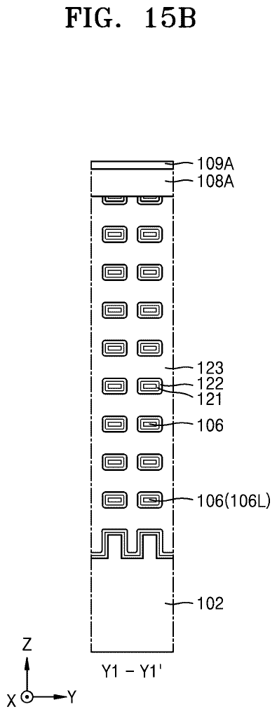

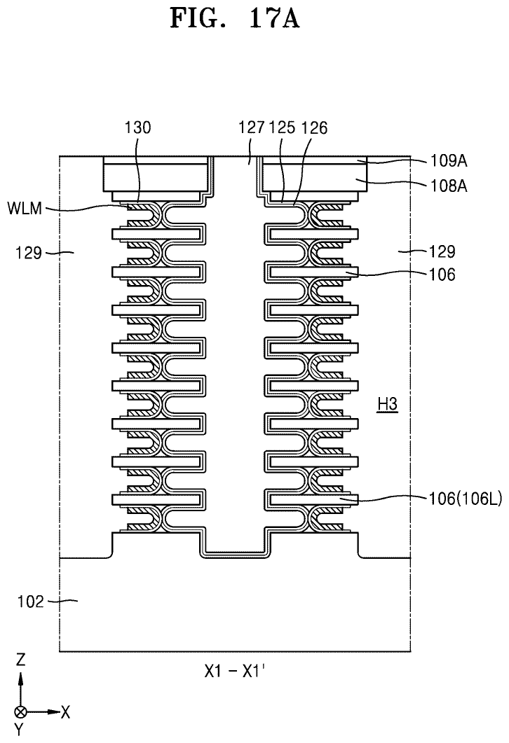

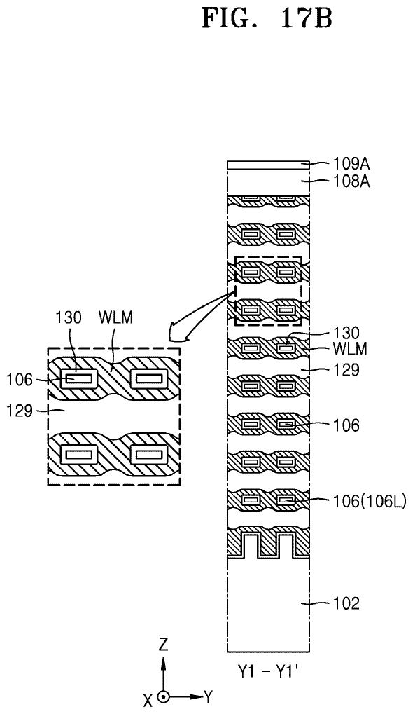

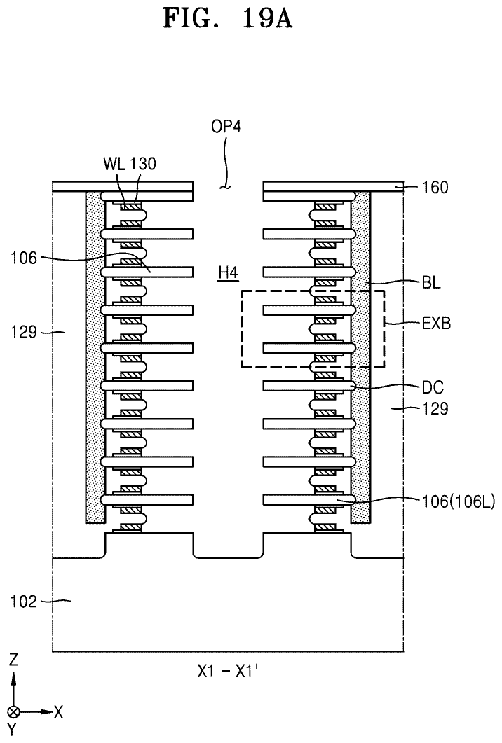

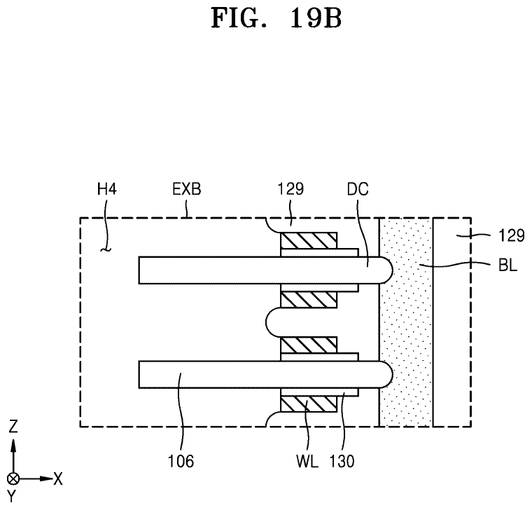

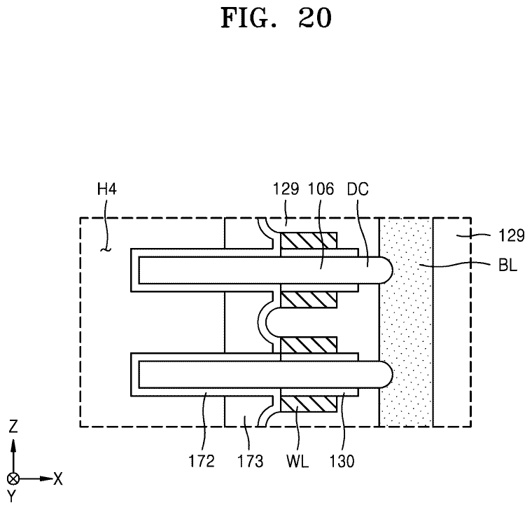

FIGS. 8 to 27 are diagrams illustrating a method of manufacturing a semiconductor memory device, according to embodiments. More specifically, FIGS. 8, 9, 10, 11, 12, 13, 14, 15A, 16, 17A, 18, and 19A are each a cross-sectional view of a partial region corresponding to a cross-section taken along line X1-X1′ of FIG. 4, according to a process sequence. FIGS. 15B and 17B are cross-sectional views of a partial region corresponding to a cross-section taken along line Y1-Y1′ of FIG. 4, according to a process sequence. FIG. 19B is an enlarged cross-sectional view of a partial region denoted by “EXB” in FIG. 19A. FIGS. 20, 21, 22, 23, 24, 25, 26, and 27 are each an enlarged cross-sectional view of a region corresponding to a partial region “EX1” of FIG. 5A, according to a process sequence. An example of a method of manufacturing the semiconductor memory device 100A shown in FIGS. 4, 5A, 5B, and 6 is described with reference to FIGS. 8 to 27. In FIGS. 8 to 27, the same reference numerals are used to denote the same elements as in FIGS. 4, 5A, 5B, and 6, and thus, repeated descriptions thereof are omitted.

Referring to FIG. 8, an amorphous insulating film 52 may be formed on a main surface 102M of a substrate 102, and then a plurality of amorphous silicon layers 106A and a plurality of sacrificial layers 104 may be alternately stacked one-by-one on the amorphous insulating film 52 in a vertical direction (Z direction).

The plurality of sacrificial layers 104 may include a material having an etch selectivity with respect to the plurality of amorphous silicon layers 106A. In embodiments, the plurality of sacrificial layers 104 may include an undoped SiGe layer, a SiGe layer doped with carbon (C), a SiGe layer doped with phosphorus (P), a silicon (Si) layer doped with carbon (C), or a Si layer doped with phosphorus (P), without being limited thereto.

A thickness in the vertical direction (Z direction) of each of the plurality of amorphous silicon layers 106A and the plurality of sacrificial layers 104 may be variously determined. For example, in the vertical direction (Z direction), a thickness of each of the plurality of amorphous silicon layers 106A may be less than a thickness of each of the plurality of sacrificial layers 104. In the vertical direction (Z direction), a thickness T1 of each of the plurality of amorphous silicon layers 106A may be less than a thickness T2 of each of the plurality of sacrificial layers 104. In embodiments, the thickness T2 of each of the plurality of sacrificial layers 104 may be at least three times greater than the thickness T1 of each of the plurality of amorphous silicon layers 106A, without being limited thereto.

A selective epitaxial growth process may not be used to form the plurality of amorphous silicon layers 106A and the plurality of sacrificial layers 104. For example, the plurality of amorphous silicon layers 106A and the plurality of sacrificial layers 104 may be formed by using a CVD process or an atomic layer deposition (ALD) process, without being limited thereto.

An uppermost surface of a stack structure including the plurality of amorphous silicon layers 106A and the plurality of sacrificial layers 104 may include a top surface of the amorphous silicon layer 106A at a highest level, from among the plurality of amorphous silicon layers 106A.

Afterwards, by using a method similar that described with reference to FIG. 1B, an alignment insulating layer 58 may be formed on the stack structure including the plurality of amorphous silicon layers 106A and the plurality of sacrificial layers 104, and a sacrificial amorphous silicon layer 60 may be formed on the alignment insulating layer 58. The sacrificial amorphous silicon layer 60 may include the same material as the amorphous silicon layer 106A. The sacrificial amorphous silicon layer 60 may be formed by using the same process as the process of forming the plurality of amorphous silicon layers 106A. In the vertical direction (Z direction), a thickness of the sacrificial amorphous silicon layer 60 may be greater than a thickness of each of the plurality of amorphous silicon layers 106A.

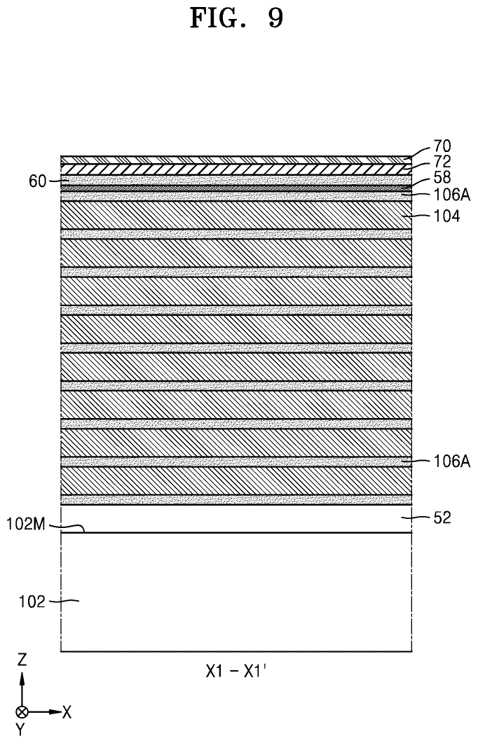

Referring to FIG. 9, similarly to that described with reference to FIG. 1B, a metal-containing layer 70 may be formed to cover a top surface of the sacrificial amorphous silicon layer 60 in the resultant structure of FIG. 8, and then the obtained resultant structure may be thermally treated, and thus, a portion of the sacrificial amorphous silicon layer 60 may be transformed into a metal silicide layer 72.

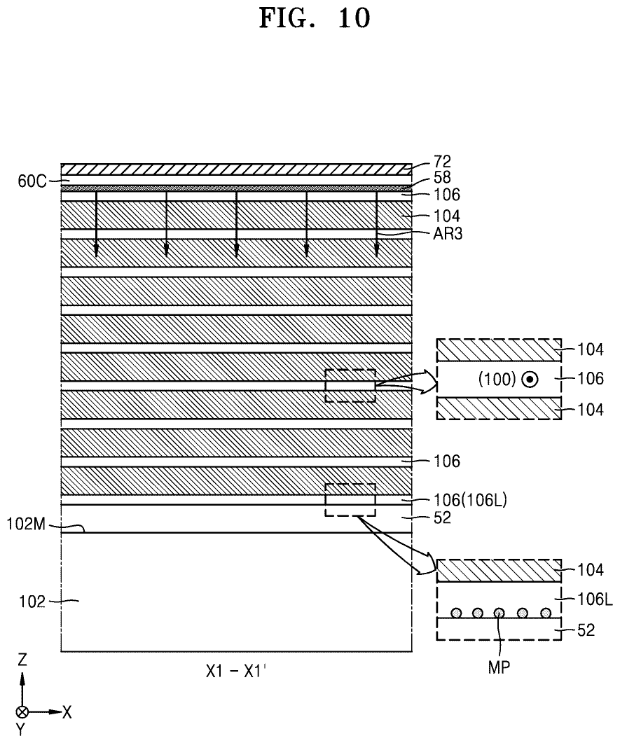

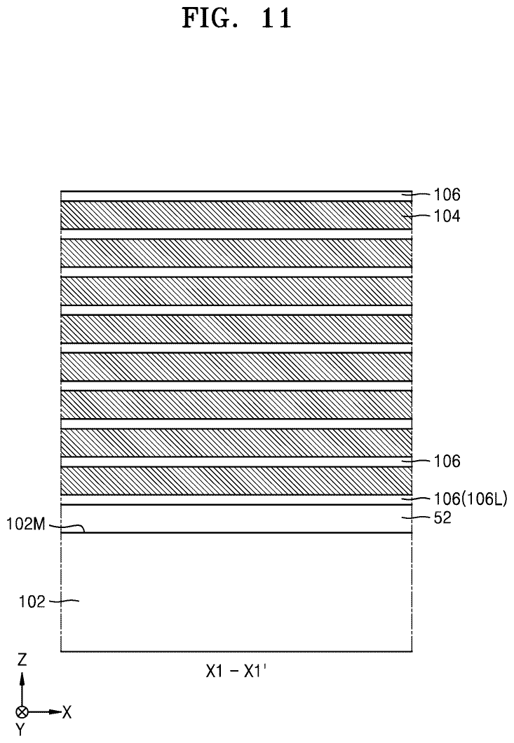

Referring to FIG. 10, the metal-containing layer 70 may be removed from the resultant structure of FIG. 9 to expose a top surface of the metal silicide layer 72. Afterwards, in a similar manner to that described with reference to FIG. 1E, a metal-induced crystallization process for crystallizing the plurality of amorphous silicon layers 106A may be performed by using the metal silicide layer 72 and the alignment insulating layer 58. To perform the metal-induced crystallization process, the resultant structure in which the metal silicide layer 72 is exposed may be thermally treated. During the metal-induced crystallization process, metal elements diffused from the metal silicide layer 72 may pass through the sacrificial amorphous silicon layer 60 and the alignment insulating layer 58 and diffuse toward the substrate 102 while passing through the plurality of amorphous silicon layers 106A in a vertical direction. After passing through the alignment insulating layer 58, the metal elements may pass through the plurality of amorphous silicon layers 106A in the vertical direction. Thus, directions in which the metal elements are diffused may be uniformly aligned in a direction toward the substrate 102 in FIG. 10 as indicated by a plurality of arrows AR3. While the metal elements are passing through the sacrificial amorphous silicon layer 60 and the plurality of amorphous silicon layers 106A in the directions of the plurality of arrows AR3, the sacrificial amorphous silicon layer 60 and the plurality of amorphous silicon layers 106A may be sequentially crystallized in the direction toward the substrate 102. As a result, a sacrificial single crystalline silicon layer 60C may be obtained from the sacrificial amorphous silicon layer 60, and a plurality of single crystalline silicon layers 106 may be obtained from the plurality of amorphous silicon layers 106A.

After the plurality of single crystalline silicon layers 106 are formed, in each of the plurality of single crystalline silicon layers 106, a surface facing a lateral direction orthogonal to the vertical direction (Z direction) may be oriented along a (100) crystal plane. In embodiments, each of the plurality of single crystalline silicon layers 106 may have a first surface facing a first lateral direction (X direction) orthogonal to the vertical direction (Z direction), a second surface facing a second lateral direction (Y direction) orthogonal to each of the vertical direction (Z direction) and the first lateral direction (X direction), and a third surface facing the vertical direction (Z direction), and each of the first surface, the second surface, and the third surface may be oriented along a (100) crystal plane.

When the substrate 102 includes a single-crystalline silicon substrate, a surface facing the second lateral direction (Y direction) of each of the plurality of single crystalline silicon layers 106 and a surface facing the second lateral direction (Y direction) of the substrate 102 may be oriented along the same crystal surface, that is, a (100) crystal plane. In contrast, in each of the plurality of single crystalline silicon layers 106, surfaces facing the vertical direction (Z direction) and the first lateral direction (X direction) may be oriented along a (100) crystal plane, and surfaces facing the vertical direction (Z direction) and the first lateral direction (X direction) of the substrate 102 may be oriented along a (110) crystal plane.

After the plurality of single crystalline silicon layers 106 are formed by using the metal-induced crystallization process, a gettering process may be performed to remove metal elements remaining in the substrate 102 and the stack structure located thereon. In this case, from among the plurality of single crystalline silicon layers 106, a lowest-level single crystalline silicon layer 106L that is closest to the substrate 102 may include metal impurities MP. From among the plurality of single crystalline silicon layers 106, other single crystalline silicon layers 106 except for the lowest-level single crystalline silicon layer 106L may not include metal impurities. The metal impurities MP may be some of metal elements, which pass through the alignment insulating layer 58 from the metal silicide layer 72 and diffuse toward the substrate 102. In embodiments, the metal impurities MP may include metal elements that remain without being removed during the gettering process, from among the metal elements diffused from the metal silicide layer 72.

In embodiments, in the lowest-level single crystalline silicon layer 106L, a content of the metal impurities MP may be in a range of greater than 0 ppm and not more than 500 ppm, for example, a range of greater than 0 ppm and not more than 200 ppm, without being limited thereto.

Referring to FIG. 11, by using a method similar to that described with reference to FIG. 1F, the metal silicide layer 72, the sacrificial single crystalline silicon layer 60C, and the alignment insulating layer 58 may be removed from the resultant structure of FIG. 10, and thus, a top surface of an uppermost one of the plurality of single crystalline silicon layers 106 may be exposed.

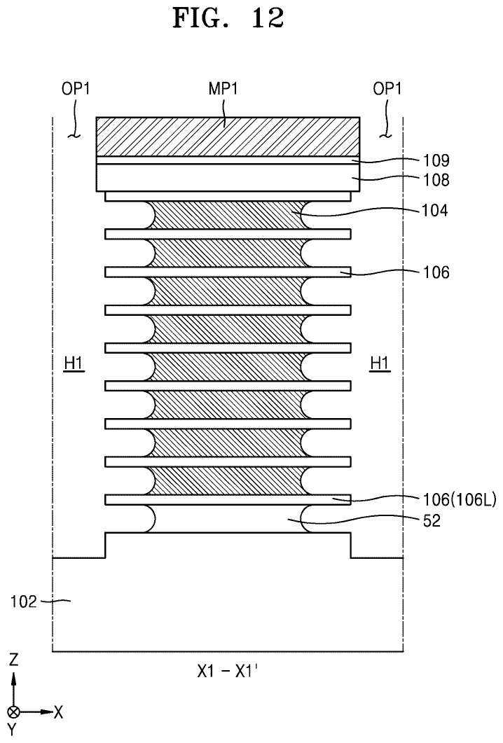

Referring to FIG. 12, a silicon oxide film and a silicon nitride film may be sequentially formed on the stack structure including the plurality of sacrificial layers 104 and the plurality of single crystalline silicon layers 106, and a mask pattern MP1 may be formed on the silicon nitride film. The mask pattern MP1 may include a plurality of first openings OP1. In embodiments, the mask pattern MP1 may include a photoresist pattern, without being limited thereto. Thereafter, the silicon nitride film and the silicon oxide film may be sequentially etched through the plurality of first openings OP1 by using the mask pattern MP1 as an etch mask to form a silicon oxide film pattern 108 and a silicon nitride film pattern 109. Subsequently, the stack structure including the plurality of sacrificial layers 104 and the plurality of single crystalline silicon layers 106 may be partially etched, and thus, a plurality of holes H1 exposing the substrate 102 may be formed in the stack structure.

Afterwards, respective portions of the plurality of sacrificial layers 104 and the amorphous insulating film 52 may be removed through the plurality of first openings OP1 and the plurality of holes H1. As a result, a structure in which the plurality of single crystalline silicon layers 106 protrude in the first lateral direction (X direction) may be obtained between the remaining portions of the plurality of sacrificial layers 104 and the amorphous insulating film 52.

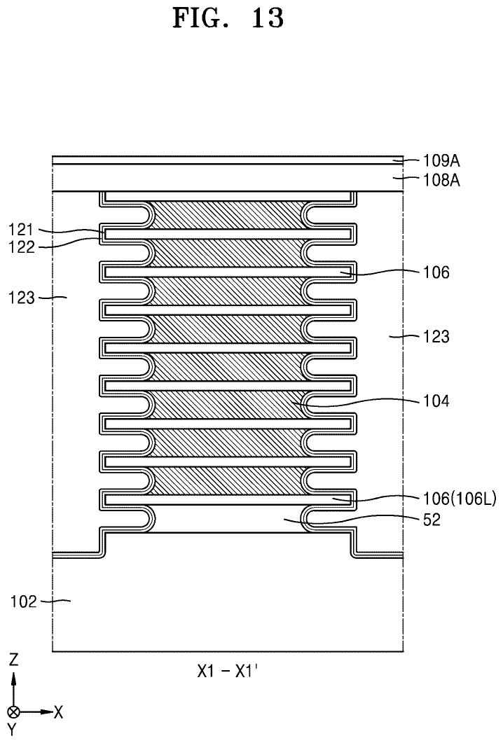

Referring to FIG. 13, in the resultant structure of FIG. 12, a first insulating liner 121 and a second insulating liner 122 may be formed to conformally cover surfaces exposed through the plurality of holes H1, and a buried insulating film 123 may be formed to fill the remaining spaces of the plurality of holes H1, which are defined by the second insulating liner 122. In embodiments, the first insulating liner 121 may include silicon oxide, the second insulating liner 122 may include silicon nitride, and the buried insulating film 123 may include silicon oxide.

Afterwards, the mask pattern MP1, the silicon oxide film pattern 108, and the silicon nitride film pattern 109 may be removed by using a CMP process. Thus, a planar top surface at which a plurality of single crystalline silicon layers 106 located at a farthest vertical level from the substrate 102, from among the plurality of single crystalline silicon layers 106, are exposed may be formed. Thereafter, a silicon oxide film 108A and a silicon nitride film 109A may be formed on the obtained resultant structure.

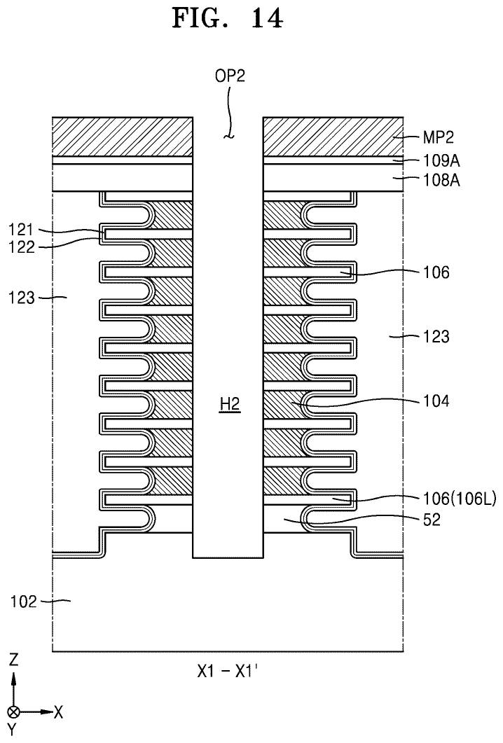

Referring to FIG. 14, a mask pattern MP2 may be formed on the silicon nitride film 109A. The mask pattern MP2 may include a second opening OP2. The second opening OP2 may be located at a position shifted in the first lateral direction (X direction) from positions of the plurality of first openings OP1 formed in the mask pattern MP1 shown in FIG. 12. In embodiments, the mask pattern MP2 may include a photoresist pattern, without being limited thereto.

The silicon nitride film 109A, the silicon oxide film 108A, the stack structure including the plurality of sacrificial layers 104 and the plurality of single crystalline silicon layers 106, and the amorphous insulating film 52 may be etched through the second opening OP2 by using the mask pattern MP2 as an etch mask to form a hole H2 exposing the substrate 102. During the formation of the hole H2, a portion of the substrate 102 may also be etched by an over-etching process, and thus, a recess region may be formed in the substrate 102 at the bottom of the hole H2.

Referring to FIGS. 15A and 15B, the plurality of sacrificial layers 104 and the amorphous insulating film 52, which are exposed through a plurality of holes H2, may be removed in the resultant structure of FIG. 14. Subsequently, a third insulating liner 125 and a fourth insulating liner 126 may be formed to conformally cover surfaces of the plurality of single crystalline silicon layers 106, which are exposed through the plurality of holes (refer to H2 in FIG. 14), and a buried insulating film 127 may be formed to fill the remaining spaces of the plurality of holes H2, which are defined by the fourth insulating liner 126. In embodiments, the third insulating liner 125 may include silicon oxide, the fourth insulating liner 126 may include silicon nitride, and the buried insulating film 127 may include silicon oxide. Thereafter, the mask pattern MP2 may be removed by using a CMP process to expose a top surface of a silicon nitride film 109A.

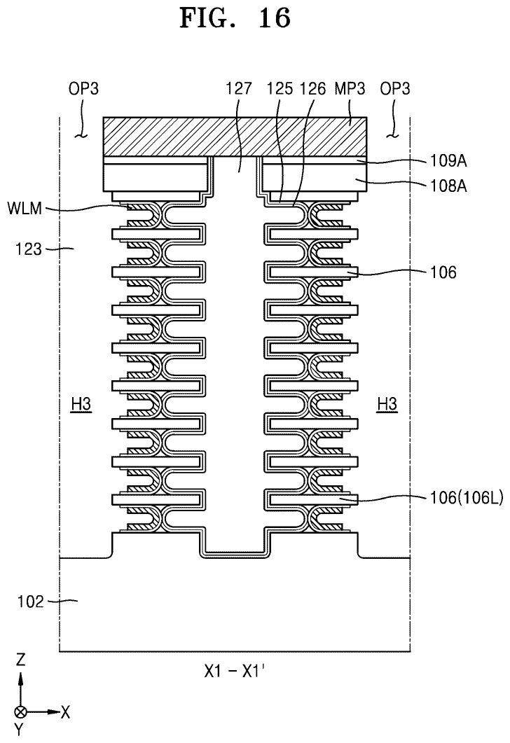

Referring to FIG. 16, a mask pattern MP3 may be formed on the resultant structure on which the processes described with reference to FIGS. 15A and 15B have been performed. The mask pattern MP3 may include a plurality of third openings OP3. The mask pattern MP3 may include a photoresist pattern, without being limited thereto.

Next, the silicon nitride film 109A and the silicon oxide film 108A may be sequentially etched through the plurality of third openings OP3 by using the mask pattern MP3 as an etch mask. Subsequently, the buried insulating film 123, the second insulating liner 122, and the first insulating liner 121 may be sequentially removed to form a plurality of holes H3 exposing the plurality of single crystalline silicon layers 106 and the substrate 102.

Thereafter, a gate dielectric film 130 may be formed to conformally cover surfaces exposed by the plurality of holes H3, a conductive layer may be formed to cover a surface of the gate dielectric film 130, and a protective pattern may be formed to cover portions of the conductive layer, which are desired to be left. Then, exposed portions of the conductive layer may be selectively removed by using the protective pattern as an etch mask to form a plurality of conductive patterns WLM for forming a plurality of word lines. Subsequently, the protective pattern may be removed.

Referring to FIGS. 17A and 17B, the mask pattern MP3 may be removed from the resultant structure of FIG. 16 to expose a top surface of a silicon nitride film 109A. Afterwards, the remaining spaces of the plurality of holes H3 by which the plurality of conductive patterns WLM are exposed may be filled by an insulating structure 129. The insulating structure 129 may include a silicon oxide film, a silicon nitride film, or a combination thereof. In embodiments, the insulating structure 129 may include a silicon oxide liner, a silicon nitride liner, and a silicon oxide film for filling, which are sequentially stacked on surfaces of the gate dielectric film 130 and the plurality of conductive patterns WLM. After the insulating structure 129 is formed, the top surface of the silicon nitride film 109A may be exposed around the insulating structure 129.

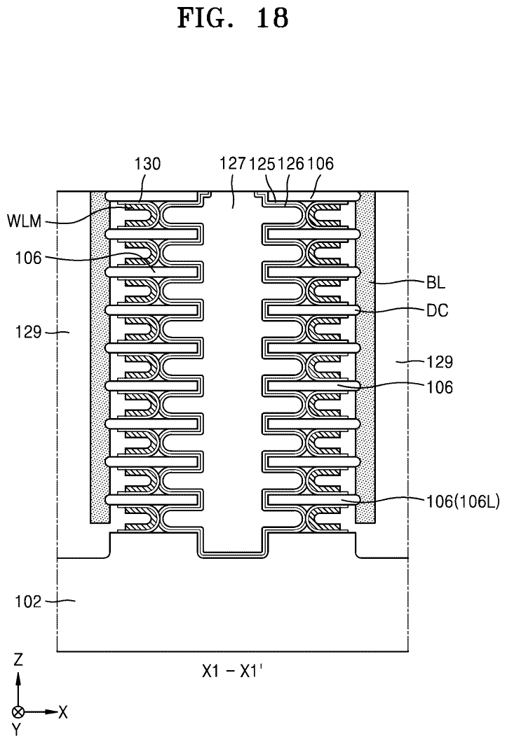

Referring to FIG. 18, in the resultant structure on which the processes described with reference to FIGS. 17A and 17B have been performed, a plurality of vertical holes may be formed to pass through a portion of the insulating structure 129 in the vertical direction (Z direction). Respective portions of the plurality of single crystalline silicon layers 106 arranged in a line in the vertical direction (Z direction) may be exposed through the plurality of vertical holes. A dopant may be doped into each of the plurality of single crystalline silicon layers 106 exposed through the plurality of vertical holes, and thus, a direct contact DC may be formed in a partial region of each of the plurality of single crystalline silicon layers 106. The dopant may include p-type or n-type impurity ions. For instance, the dopant may include boron (B), phosphorus (P), or arsenic (As), without being limited thereto.

Thereafter, a plurality of bit lines BL may be formed inside the plurality of vertical holes. Each of the plurality of bit lines BL may be formed to be in contact with the plurality of single crystalline silicon layers 106, which are arranged in a line in the vertical direction (Z direction). Afterwards, the silicon nitride film 109A and the silicon oxide film 108A may be removed by using a CMP process. Thus, a planar top surface at which a plurality of single crystalline silicon layers 106 located at a farthest vertical level from the substrate 102, from among the plurality of single crystalline silicon layers 106, are exposed may be formed.

Referring to FIGS. 19A and 19B, a mask pattern 160 may be formed to cover the resultant structure on which the processes described with reference to FIG. 18 have been performed. The mask pattern 160 may include a fourth opening OP4. In a view from above, a position of the fourth opening OP4 may be the same as or similar to the position of the second opening OP2 shown in FIG. 14. The mask pattern 160 may include a silicon nitride film.

The buried insulating film (refer to 127 in FIG. 18), the fourth insulating liner (refer to 126 in FIG. 18), and the third insulating liner (refer to 125 in FIG. 18) may be removed through the fourth opening OP4. Thus, a hole H4 may be formed to expose the plurality of single crystalline silicon layers 106, a plurality of gate dielectric films 130, and the substrate 102. Thereafter, exposed portions of the plurality of gate dielectric films 130 may be partially removed through the hole H4 to expose the plurality of conductive patterns (refer to WLM in FIG. 18). Respective portions of the plurality of conductive patterns WLM, which are exposed, may be etched to form a plurality of word lines WL from the plurality of conductive patterns WLM. As a result, as shown in the enlarged view of FIG. 19B, the insulating structure 129 may be exposed around the word line WL surrounding the single crystalline silicon layer 106 inside the hole H4.

Referring to FIG. 20, an insulating liner 172 may be formed to conformally cover a surface of each of the plurality of word lines WL, the plurality of gate dielectric films 130, and the insulating structure 129, which are exposed inside the hole H4. Thereafter, a buried insulating film 173 may be formed on the insulating liner 172 to partially fill respective spaces between the plurality of single crystalline silicon layers 106. The buried insulating film 173 may be formed to surround a portion of each of the plurality of single crystalline silicon layers 106 with the insulating liner 172 therebetween. After the buried insulating film 173 is formed, portions of the plurality of single crystalline silicon layers 106 and the insulating liner 172 covering the plurality of single crystalline silicon layers 106 may protrude in the first lateral direction (X direction) over a sidewall of the buried insulating film 173 inside the hole H4.

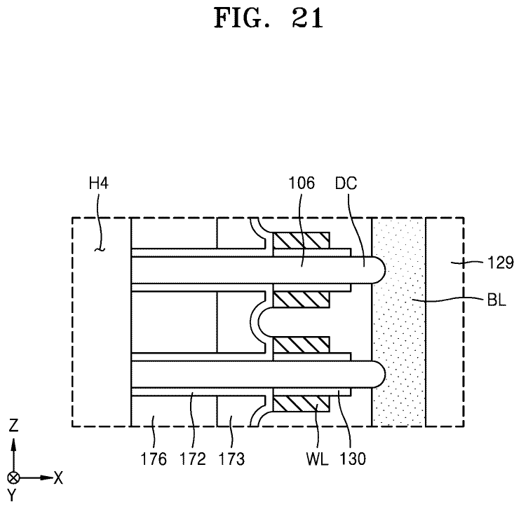

Referring to FIG. 21, in the resultant structure of FIG. 20, an insulating pattern 176 may be formed to fill respective spaces between the plurality of single crystalline silicon layers 106 through the hole H4, and the insulating liner 172 may be partially removed to expose a sidewall of each of the plurality of single crystalline silicon layers 106. The insulating pattern 176 may include a silicon oxide film, a silicon nitride film, or a combination thereof.

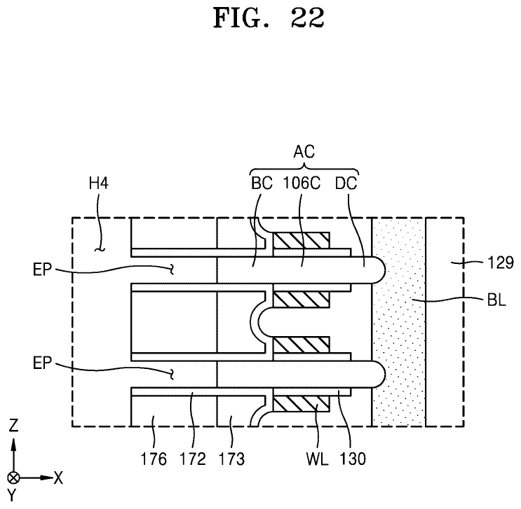

Referring to FIG. 22, a portion of each of the plurality of single crystalline silicon layers 106 exposed through the hole H4 may be removed from the resultant structure on which the processes described with reference to FIG. 21 have been performed, and thus, a plurality of electrode spaces EP may be formed. Next, a dopant may be doped into the plurality of single crystalline silicon layers 106 through the hole H4 and the plurality of electrode spaces EP, and thus, a buried contact BC may be formed in each of the plurality of single crystalline silicon layers 106. In embodiments, the dopant may include p-type or n-type impurity ions. For example, the dopant may include boron (B), phosphorus (P), or arsenic (As), without being limited thereto.

After the buried contact BC is formed in each of the plurality of single crystalline silicon layers 106, the remaining portion of each of the single crystalline silicon layers 106 may be a channel region 106C. Each of a plurality of active regions AC may include the channel region 106C and the buried contact BC and the direct contact DC, which are spaced apart from one another with the channel region 106C therebetween in the first lateral direction (X direction).

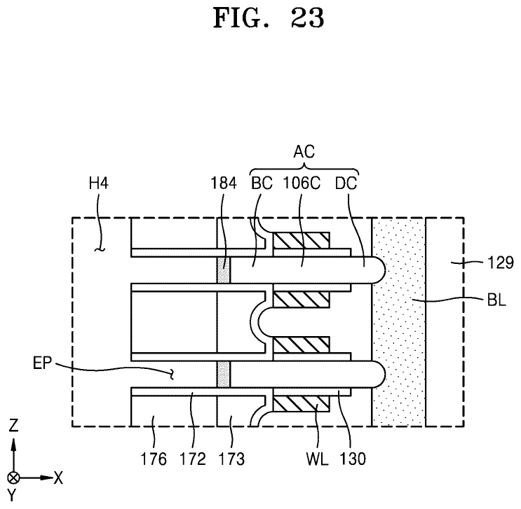

Referring to FIG. 23, a metal silicide film 184 may be formed on a surface of each of a plurality of active regions AC exposed at the plurality of electrode spaces EP. In embodiments, the formation of the metal silicide film 184 may include forming a metal-silicon composite layer by vapor-depositing a metal and silicon on a surface of each of the plurality of active regions AC and siliciding the metal-silicon composite layer by using a thermal treatment process or an annealing process.

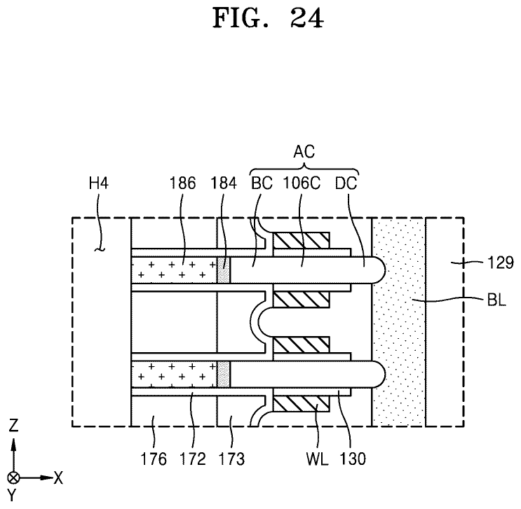

Referring to FIG. 24, a conductive layer may be formed to conformally cover surfaces exposed by the hole H4 and the plurality of electrode spaces EP, and then portions of the conductive layer, which are located outside the plurality of electrode spaces EP, may be removed to form a plurality of first electrodes 186.

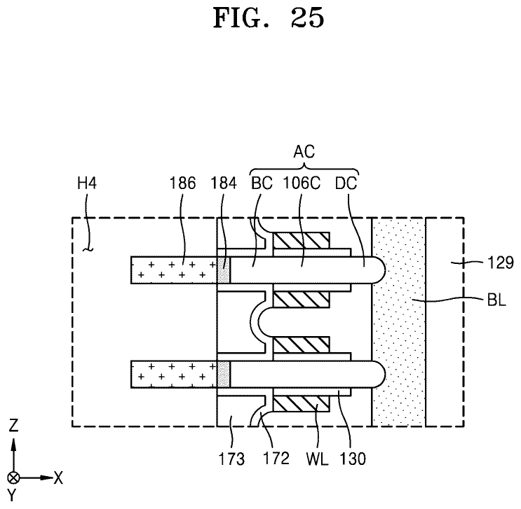

Referring to FIG. 25, in the resultant structure in which the processes described with reference to FIG. 24 have been performed, the insulating pattern 176 may be removed through the hole H4, and the insulating liner 172 may be partially removed to further expose respective surfaces of the plurality of first electrodes 186.

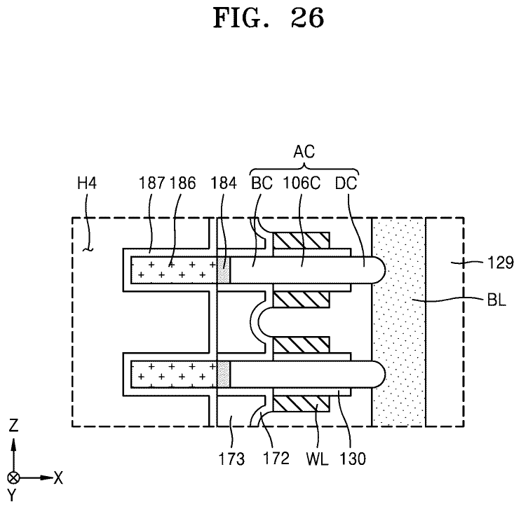

Referring to FIG. 26, a dielectric film 187 may be formed to conformally cover the respective surfaces of the plurality of first electrodes 186, which are exposed through the hole H4, and surfaces of the buried insulating film 173.

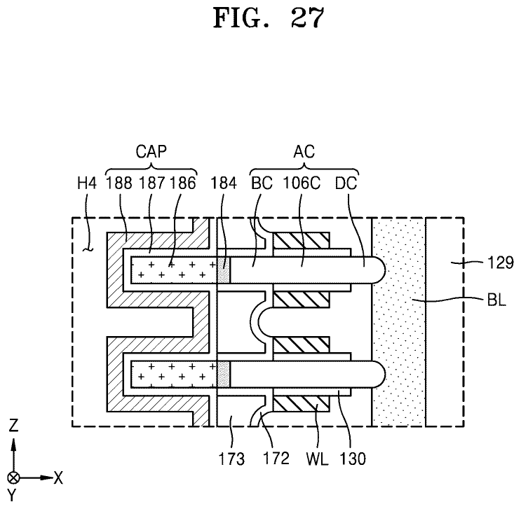

Referring to FIG. 27, a second electrode 188 covering the dielectric film 187 may be formed through the hole H4 to form a plurality of capacitors CAP.

Thereafter, a plate electrode 190 covering the second electrode 188 may be formed inside the hole H4, and thus, the semiconductor memory device 100A shown in FIGS. 4, 5A, 5B, and 6 may be manufactured.

To manufacture the semiconductor memory device 200 shown in FIG. 7, the processes described with reference to FIGS. 8 to 27 may be performed. However, in the processes described with reference to FIG. 8, the resultant structure in which a peripheral circuit structure PCS is formed on the substrate 252 shown in FIG. 7 may be used instead of the substrate 102. That is, the peripheral circuit structure PCS may be formed on the substrate 252. After the peripheral circuit structure PCS is formed, the interlayer insulating film 270 may have a planarized top surface. Thereafter, the amorphous insulating film 52 shown in FIG. 8 may be formed on the interlayer insulating film 270, and a stack structure in which a plurality of amorphous silicon layers 106A and a plurality of sacrificial layers 104 are alternately stacked one-by-one in the vertical direction (Z direction) may be formed on the amorphous insulating film 52. An alignment insulating layer 58 and a sacrificial amorphous silicon layer 60 may be formed on the stack structure. Subsequently, the processes described with reference to FIGS. 9 to 27 may be performed.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a substrate; and
a plurality of single crystalline silicon layers arranged in a line in a vertical direction on the substrate and spaced apart from one another in the vertical direction,
wherein, in each of the plurality of single crystalline silicon layers, a surface facing a lateral direction substantially orthogonal to the vertical direction is oriented along a (100) crystal plane, and,
from among the plurality of single crystalline silicon layers, a lowest-level single crystalline silicon layer closest to the substrate comprises metal impurities.

2. The semiconductor memory device of claim 1, wherein, in the lowest-level single crystalline silicon layer, a content of the metal impurities is greater than 0 ppm and not more than 500 ppm.

3. The semiconductor memory device of claim 1, wherein each of the plurality of single crystalline silicon layers comprises a first surface facing a first lateral direction substantially orthogonal to the vertical direction, a second surface facing a second lateral direction substantially orthogonal to each of the vertical direction and the first lateral direction, and a third surface facing the vertical direction, and
each of the first surface, the second surface, and the third surface is oriented along a (100) crystal plane.

4. The semiconductor memory device of claim 3, wherein the substrate comprises a single-crystalline silicon substrate, and,
in the single-crystalline silicon substrate, surfaces facing the vertical direction and the first lateral direction are oriented along a (110) crystal plane, and a surface facing the second lateral direction is oriented along a (100) crystal plane.

5. The semiconductor memory device of claim 1, wherein, from among the plurality of single crystalline silicon layers, other single crystalline silicon layers except for the lowest-level single crystalline silicon layer do not comprise metal impurities.

6. The semiconductor memory device of claim 1, wherein the metal impurities comprise nickel (Ni), palladium (Pd), titanium (Ti), silver (Ag), gold (Au), aluminum (Al), tin (Sn), antimony (Sb), copper (Cu), cobalt (Co), molybdenum (Mo), ruthenium (Ru), rhodium (Rh), cadmium (Cd), platinum (Pt), or a combination thereof.

7. The semiconductor memory device of claim 1, wherein, in each of the plurality of single crystalline silicon layers, a surface facing the vertical direction is oriented along a (100) crystal plane, and
the substrate comprises a single-crystalline silicon substrate in which a surface facing the vertical direction is oriented along a (110) crystal plane.

8. The semiconductor memory device of claim 1, further comprising an amorphous insulating film between the substrate and the lowest-level single crystalline silicon layer, the amorphous insulating film being in contact with a top surface of the substrate,
wherein:
the lowest-level single crystalline silicon layer is spaced apart in the vertical direction from the substrate with the amorphous insulating film therebetween, and
the amorphous insulating film comprises a silicon oxide film, a silicon nitride film, a silicon oxynitride film, or a combination thereof.

9. A semiconductor memory device comprising:
a substrate; and
a memory cell block comprising a plurality of memory cells arranged on the substrate, the memory cell block having a three-dimensional structure,
wherein the plurality of memory cells are repeatedly arranged in a first lateral direction, a second lateral direction, and a vertical direction and each comprise a plurality of active regions, each of which comprises a single crystalline silicon layer, wherein the first lateral direction and the second lateral direction are substantially orthogonal to one another, and the vertical direction is substantially perpendicular to each of the first lateral direction and the second lateral direction,
in each of the plurality of active regions, a first surface facing the second lateral direction is oriented along a (100) crystal plane, and,
from among the plurality of active regions, lowest-level active regions closest to the substrate in the vertical direction comprise metal impurities.

10. The semiconductor memory device of claim 9, wherein, from among the plurality of active regions, active regions that are spaced apart in the vertical direction from the substrate with the lowest-level active regions therebetween do not comprise metal impurities.

11. The semiconductor memory device of claim 9, wherein, in each of the lowest-level active regions, a content of the metal impurities is more than 0 ppm and not more than 500 ppm.

12. The semiconductor memory device of claim 9, wherein, in each of the plurality of active regions, a second surface facing the first lateral direction and a third surface facing the vertical direction are each oriented along a (100) crystal plane.

13. The semiconductor memory device of claim 9, wherein the substrate comprises a single-crystalline silicon substrate, and,
in the single-crystalline silicon substrate, surfaces facing the vertical direction and the first lateral direction are oriented along a (110) crystal plane, and a surface facing the second lateral direction is oriented along a (100) crystal plane.

14. The semiconductor memory device of claim 9, wherein the metal impurities comprise nickel (Ni), palladium (Pd), titanium (Ti), silver (Ag), gold (Au), aluminum (Al), tin (Sn), antimony (Sb), copper (Cu), cobalt (Co), molybdenum (Mo), ruthenium (Ru), rhodium (Rh), cadmium (Cd), platinum (Pt), or a combination thereof.

15. The semiconductor memory device of claim 9, wherein, in each of the plurality of active regions, a surface facing the vertical direction is oriented along a (100) crystal plane, and
the substrate comprises a single-crystalline silicon substrate in which a surface facing the vertical direction is oriented along a (110) crystal plane.

16. The semiconductor memory device of claim 9, further comprising a peripheral circuit structure between the substrate and the memory cell block.

17. A semiconductor memory device comprising:
a substrate; and
a memory cell block having a three-dimensional structure, the memory cell block comprising a plurality of memory cells that are repeatedly arranged on a main surface of the substrate in a first lateral direction, a second lateral direction, and a vertical direction, wherein the first lateral direction and the second lateral direction are substantially parallel to the main surface and substantially orthogonal to one another, and the vertical direction is substantially perpendicular to the main surface of the substrate,
wherein the memory cell block comprises:
a plurality of active regions arranged in a line in the vertical direction on the substrate, each active region comprising a single crystalline silicon layer;
a plurality of word lines, each word line surrounding a selected one of the plurality of active regions and extending in the second lateral direction, the plurality of word lines overlapping one another in the vertical direction;
a bit line extending in the vertical direction on the substrate, the bit line being connected to one side of each of the plurality of active regions; and
a plurality of capacitors, each capacitor comprising a first electrode configured to be connected to another side of a selected one of the plurality of active regions,
wherein, in each of the plurality of active regions, a first surface facing the second lateral direction is oriented along a (100) crystal plane,
from among the plurality of active regions, a lowest-level active region closest to the substrate in the vertical direction comprises metal impurities, and,
from among the plurality of active regions, active regions that are spaced apart in the vertical direction from the substrate with the lowest-level active region therebetween do not comprise metal impurities.

18. The semiconductor memory device of claim 17, wherein, in the lowest-level active region, a content of the metal impurities is more than 0 ppm and not more than 500 ppm, and
the metal impurities comprise nickel (Ni), palladium (Pd), titanium (Ti), silver (Ag), gold (Au), aluminum (Al), tin (Sn), antimony (Sb), copper (Cu), cobalt (Co), molybdenum (Mo), ruthenium (Ru), rhodium (Rh), cadmium (Cd), platinum (Pt), or a combination thereof.

19. The semiconductor memory device of claim 17, wherein, in each of the plurality of active regions, a second surface facing the first lateral direction and a third surface facing the vertical direction are each oriented along a (100) crystal plane.

20. The semiconductor memory device of claim 17, wherein the substrate comprises a single-crystalline silicon substrate, and,
in the single-crystalline silicon substrate, surfaces facing the vertical direction and the first lateral direction are oriented along a (110) crystal plane, and a surface facing the second lateral direction is oriented along a (100) crystal plane.
